(19) United States
(12) Patent Application Publication
(10) Pub. No.: US 2025/0251466 A1
(43) Pub. Date: Aug. 7, 2025

(54) CURRENT LEAKAGE DETECTION DEVICE

(71) Applicant: DENSO CORPORATION, Kariya-city (JP)

(72) Inventor: Tomomichi MIZOGUCHI, Kariya-city (JP)

(73) Assignee: DENSO CORPORATION, Kariya-city (JP)

(21) Appl. No.: 19/184,336

(22) Filed: Apr. 21, 2025

Related U.S. Application Data
(63) Continuation of application No. PCT/JP2023/035383, filed on Sep. 28, 2023.

(30) Foreign Application Priority Data
Oct. 21, 2022 (JP) 2022-169414
Jan. 30, 2023 (JP) 2023-012215

(51) Int. Cl. G01R 31/52; G01R 31/14

(52) U.S. Cl. CPC G01R 31/52; G01R 31/14

(57) ABSTRACT

A current leakage detection unit includes a first voltage dividing circuit, a resistor circuit connected in parallel with the first voltage dividing circuit, a switching unit that is configured to be switchable between energized and de-energized states of the resistor circuit, and a control unit that controls switching of the switching unit to acquire first voltage-dividing values from the first voltage dividing circuit and calculate an insulation resistance from the acquired voltage-dividing values to detect the current leakage. The first voltage dividing circuit includes a range change circuit that changes the voltage-dividing ratio of the first voltage dividing circuit. The control unit is configured to, when the first voltage-dividing values of the first voltage dividing circuit are less than the threshold value, change the voltage-dividing ratio of the first voltage dividing circuit to increase the first voltage-dividing value.

### CROSS-REFERENCE TO RELATED APPLICATION

This application is a continuation application of International Application No. PCT/JP2023/035383 filed Sep. 28, 2023 which designated the U. S. and claims priority to Japanese Patent Application No. 2022-169414 filed with the Japan Patent Office on Oct. 21, 2022, and Japanese Patent Application No. 2023-012215 filed with the Japan Patent Office on Jan. 30, 2023, the contents of each of which are incorporated herein by reference.

### BACKGROUND

### Technical Field

This disclosure relates to a current leakage detection device.

### Related Art

Conventionally, vehicles such as hybrid or electric vehicles are equipped with high-voltage batteries and include high-voltage circuits. In such vehicles, high-voltage circuits are typically electrically insulated from their vehicle bodies (body ground or frame ground) for safety reasons. In these cases, current leakage detection devices (insulation resistance detection circuits) are commonly provided to detect an insulating state (ground fault) between the high-voltage circuit and the vehicle body.

A known insulation resistance detection circuit of this type is configured to detect insulation resistance and detect a decrease in detection accuracy due to aging deterioration or poor contact of detection resistors constituting a voltage-dividing circuit.

### BRIEF DESCRIPTION OF THE DRAWINGS

In the accompanying drawings:

FIG. 1 is a schematic diagram of an on-board power supply system;

FIG. 2 is a flowchart of a current leakage detection process;

FIG. 3 is a flowchart of a switching process;

FIG. 4 is a flowchart of a calculation process;

FIG. 5 is a flowchart of a characteristic determination process;

FIG. 6 is a flowchart of an insulation resistance calculation process;

FIG. 7 is an illustration of calculations of various values;

FIG. 8 is a timing diagram illustrating detection timings;

FIG. 9 is a timing diagram illustrating detection timings;

FIG. 10 is an illustration of the detection accuracy according to a comparative example;

FIG. 11 is an illustration of the detection accuracy according to the present disclosure;

FIG. 12 is a schematic diagram of an on-board power supply system according to an exemplary modification;

FIG. 13 is an illustration of calculations of various values according to an exemplary modification;

FIG. 14 is a schematic diagram of an on-board power supply system according to an exemplary modification;

FIG. 15 is a schematic diagram of an on-board power supply system according to an exemplary modification;

FIG. 16 is a schematic diagram of an on-board power supply system according to an exemplary modification;

FIG. 17 is an illustration of calculations of various values according to an exemplary modification;

FIG. 18 is a flowchart of a current leakage detection process according to an exemplary modification;

FIG. 19 is an illustration of calculations of various values according to an exemplary modification;

FIG. 20 is a schematic diagram of an on-board power supply system according to a second embodiment;

FIG. 21 is an illustration of detection ranges and ON/OFF states of switches;

FIG. 22 is a flowchart of a current leakage detection process according to the second embodiment;

FIG. 23 is a flowchart of a range switching process;

FIG. 24 is a flowchart of a detection process;

FIG. 25 is a flowchart of an insulation resistance calculation process according to the second embodiment;

FIG. 26 is an illustration of calculations of various values according to the second embodiment; and

FIG. 27 is a timing diagram of switching between detection ranges.

### DESCRIPTION OF SPECIFIC EMBODIMENTS

In the known insulation resistance detection circuit as disclosed in JP 2021-50964 A, as the insulation resistance to ground Rn (negative-side insulation resistance) between the ground that defines the reference potential for the high-voltage electrical circuit and the vehicle-side ground decreases, the detected voltage becomes lower. When the detected voltage becomes too low, the detection error may become too large with the resolution of the insulation resistance detection circuit, failing to determine the current leakage correctly.

In view of the foregoing, it is desired to have a current leakage detection device capable of performing current leakage detection with high accuracy.

A current leakage detection device for detecting a current leakage between ground and power supply paths connected to terminals of a battery is provided to address the above issues. The current leakage detection device includes: a first voltage dividing circuit connected to a power supply path side at one end and connected to a ground side at another end; a resistor circuit connected in parallel with the first voltage dividing circuit with one end connected to the power supply path side and another end connected to the ground side; a switch unit configured to be switchable between energized and de-energized states of the resistor circuit; a control unit configured to control switching of the switch unit to acquire a first voltage-dividing value from the first voltage dividing circuit and calculate an insulation resistance from the acquired first voltage-dividing value to detect the current leakage. The first voltage dividing circuit includes a range change circuit that changes a voltage-dividing ratio of the first voltage dividing circuit. The control unit is configured to, when the first voltage-dividing value of the first voltage dividing circuit is less than a threshold value, change the voltage-dividing ratio of the first voltage dividing circuit to increase the first voltage-dividing value.

With this configuration, in the case where the first voltage-dividing value is less than the threshold value, the control unit changes the voltage-dividing ratio so that the first voltage-dividing value increases, allowing the resolution to be substantially reduced without changing the resolution of the control unit. Therefore, even when the insulation resistance decreases, this allows current leakage detection to be performed with high accuracy by reducing detection errors.

A current leakage detection device for detecting a current leakage between a positive-side power supply path connected to a positive terminal of a battery and ground, and a current leakage between a negative-side power supply path connected to a negative terminal of the battery and ground is provided to address the above issues. The current leakage detection device includes: a first voltage dividing circuit connected to a first power supply path that is either the positive-side power supply path or the negative-side power supply path at one end, and connected to a ground side at another end; a resistor circuit connected to the first power supply path at one end and connected to the ground side at another end, and connected in parallel with the first voltage dividing circuit; a switch unit configured to be switchable between energized and de-energized states of the resistor circuit; a control unit configured to detect a current leakage by controlling switching of the switching unit to acquire first voltage-dividing values from the first voltage dividing circuit and calculate an insulation resistance from the acquired first voltage-dividing values; and a resistor connected to, at one end, a second power supply path that is different from the first power supply path, among the positive-side power supply path and the negative-side power supply path, and connected to the ground side at another end.

With this configuration, effects of increased insulation resistance can be suppressed.

Hereinafter, the first embodiment in which the “current leakage detection device” is applied to the on-board power supply system of a vehicle equipped with a rotating electric machine as the on-board prime mover (e.g., a hybrid vehicle or an electric vehicle) will now be described with reference to the accompanying drawings. In each embodiment hereinafter, parts that are the same or equivalent to each other will be assigned the same numerals in the figures, and the descriptions will now be described for the parts with the same numerals.

### FIRST EMBODIMENT

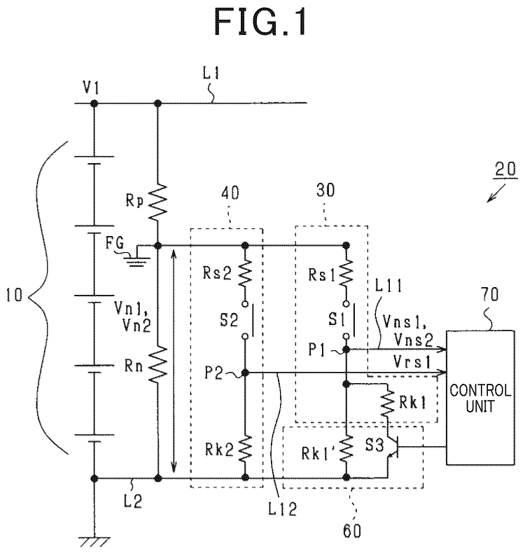

The on-board power supply system illustrated in FIG. 1 includes an assembled battery 10, a current leakage detection device 20, etc. Although not shown and not described here, an electrical load such as a rotating electric machine is connected to the positive side power supply path L1 and the negative side power supply path L2, which are connected to the assembled battery 10.

The assembled battery 10 is a rechargeable battery with a voltage of, for example, 800 V across the rechargeable battery. The assembled battery 10 is formed of a plurality of battery cells connected. For example, rechargeable lithium-ion batteries or nickel metal hydride batteries may be used as battery cells.

The positive side power supply path L1 (corresponding to the power supply line), which is connected to the positive terminal of the assembled battery 10, is electrically isolated from the vehicle side ground FG, such as a vehicle body. The vehicle side ground FG may be the vehicle body and corresponds to the frame ground. The insulating state (ground insulation resistance) between this positive side power supply path L1 and the vehicle side ground FG is represented by insulation resistance Rp.

Similarly, the negative side power supply path L2, which is connected to the negative terminal of the assembled battery 10, is electrically isolated from the vehicle side ground FG. The insulating state (ground insulation resistance) between this negative side power supply path L2 and the vehicle side ground FG is represented by insulation resistance Rn. The negative side power supply path L2 corresponds to the ground (signal ground SG) that defines a reference potential for the high-voltage electrical circuit.

The current leakage detection device 20 is connected to the vehicle side ground FG and the negative side power supply path L2, and detects whether the positive side power supply path L1 and the negative side power supply path L2 are normally isolated from the vehicle side ground FG, that is, whether there is a current leakage (ground fault).

This leakage current detection device 20 will now be described in detail. The leakage current detection device 20 includes a first voltage dividing circuit 30, a second voltage dividing circuit 40 connected in parallel with the first voltage dividing circuit 30, a first switch S1, a second switch S2, and a control unit 70 as a control unit that detects a current leakage.

The first voltage dividing circuit 30 is connected between the vehicle side ground FG and the negative-side power supply path L2, and divides the voltage between the negative-side power supply path L2 and the vehicle side ground FG (the voltage across the first voltage dividing circuit 30) by a voltage divider ratio α or α′.

Describing the configuration of the first voltage dividing circuit 30 in more detail, the first voltage dividing circuit 30 includes a first A detection resistor Rs1, a first B detection resistor Rk1′, and a first C detection resistor Rk1. The first C detection resistor Rk1 is connected in parallel with the first B detection resistor Rk1′. A parallel connection of the first C-detection resistor Rk1 and the first B-detection resistor Rk1′ is connected in series with the first A-detection resistor Rs1.

The first A detection resistor Rs1 is connected to the vehicle side ground FG, and the parallel connection of the first B detection resistor Rk1′ and the first C detection resistor Rk1 is connected to the negative-side power supply path L2. One end of the first output line L11 is connected to a first connection point P1 between the first A detection resistor Rs1 and the parallel connection of the first B detection resistor Rk1′ and the first C detection resistor Rk1. A voltage signal (first voltage-dividing value) from the first voltage dividing circuit 30 is output via the first output line L11.

A third switch S3 is connected in series with the first C detection resistor Rk1, and the third switch S3 is configured to switch between the energized state and the de-energized state. When the third switch S3 is turned on, the first C detection resistor Rk1 is energized and the voltage divider ratio of the first voltage dividing circuit 30 becomes a. When the third switch S3 is turned off, the first C detection resistor Rk1 is de-energized and the voltage divider ratio of the first voltage dividing circuit 30 becomes a′.

This third switch S3 is turned on or off by the control unit 70. The resistance value of the first B detection resistor Rk1′ is much greater than, for example, about ten times, that of the first C detection resistor Rk1. Therefore, the voltage-dividing ratio α′ is greater than the voltage-dividing ratio α, and the detection voltage rises when the third switch S3 is turned off. For example, in the case of the resistance value of the first B detection resistor Rk1′ being 10 times that of the first C detection resistor Rk1, the voltage-dividing value (voltage signal) will also increase by a factor of about 10. That is, during normal operation, in the case of a detection range of 0 to V1, when the third switch S3 is turned off, the detection range will become a range of 0 to V1/10. In the present embodiment, the first B detection resistor Rk1′ and the third switch S3 correspond to a range change circuit 60.

The second voltage dividing circuit 40 is connected between the negative-side power supply path L2 and the vehicle-side ground FG, and divides a voltage between the negative-side power supply path L2 and the vehicle-side ground FG (a voltage across the second voltage dividing circuit 40) at the voltage-dividing ratio β. The second voltage dividing circuit 40 corresponds to a resistance circuit. In the first embodiment, the negative-side power supply path L2 corresponds to a first power supply path, and the positive-side power supply path L1 corresponds to a second power supply path. Describing the second voltage dividing circuit 40 in more detail, the second voltage dividing circuit 40 includes a series connection of a second A detection resistor Rs2 and a second B detection resistor Rk2. The second A detection resistor Rs2 is connected to the vehicle side ground FG, and the second B detection resistor Rk2 is connected to the negative-side power supply path L2. One end of the second output line L12 is connected to a second connection point P2 between the second detection resistor Rs2 and the second detection resistor Rk2, and a voltage signal (second voltage-dividing value) from the second voltage dividing circuit 40 is output via the second output line L12.

Next, the first switch S1 and the second switch S2 will now be described. The first switch S1 and the second switch S2 are configured to be controlled to turn on and off by the control unit 70. The first switch S1 is operable to switch between the energized state and the de-energized state of the first voltage dividing circuit 30. In addition, the second switch S2 is operable to switch between the energized state and the de-energized state of the second voltage dividing circuit 40.

Specifically, the first switch S1 is connected between the first connection point P1 and the first A detection resistor Rs1, and is operable to connect and disconnect between the first connection point P1 and the first A detection resistor Rs1. The second switch S2 is connected between the second connection point P2 and the second detection resistor Rs2, and is operable to connect and disconnect between the second connection point P2 and the second detection resistor Rs2. The second switch S2 corresponds to a switching unit.

The control unit 70 is mainly configured as a microcomputer including a CPU, a ROM, a RAM, and I/O, etc. The CPU executes the program stored in the ROM, thereby implementing various functions. The various functions may be implemented by electronic circuits, which are hardware, or they may be implemented at least in part by software, that is, by processes performed on the computer. The control unit 70 has functions to control the on-off state of the first and second switches S1 and S2, to control the on-off state of the third switch S3, and to detect a current leakage. In addition to the control unit 70, a switch control unit having a function to control the on-off states of various types of control switches, etc., may be provided to detect a current leakage in cooperation with the control unit 70.

The control unit 70 estimates the insulation resistances Rp, Rn based on the voltage signal (first voltage-dividing value) input from the first dividing circuit 30 to detect a current leakage. However, as the insulation resistance Rn decreases, the first voltage-dividing value also decreases. When the first voltage-dividing value becomes too small, the detection error may become too large with the resolution of the control unit 70, failing to determine the current leakage correctly. To prevent the first voltage-dividing value from becoming too small, a range change circuit 60 is provided to allow the first voltage-dividing ratio to be variable.

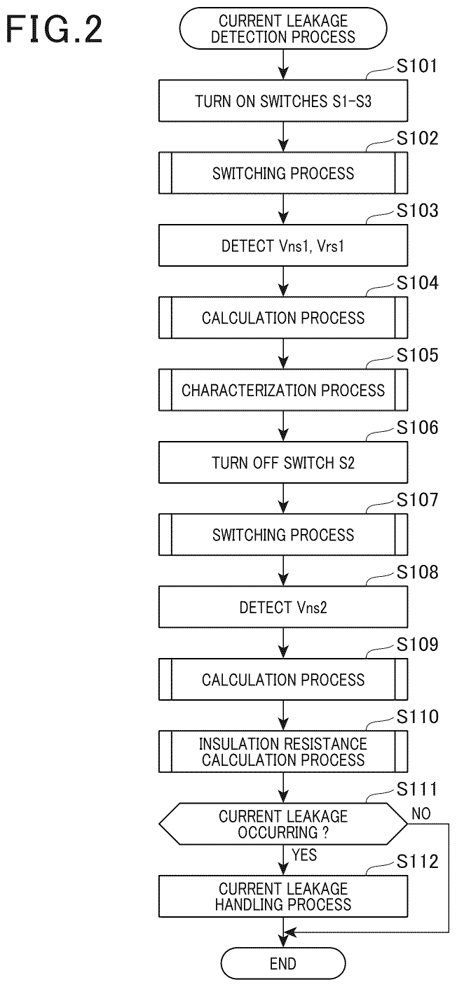

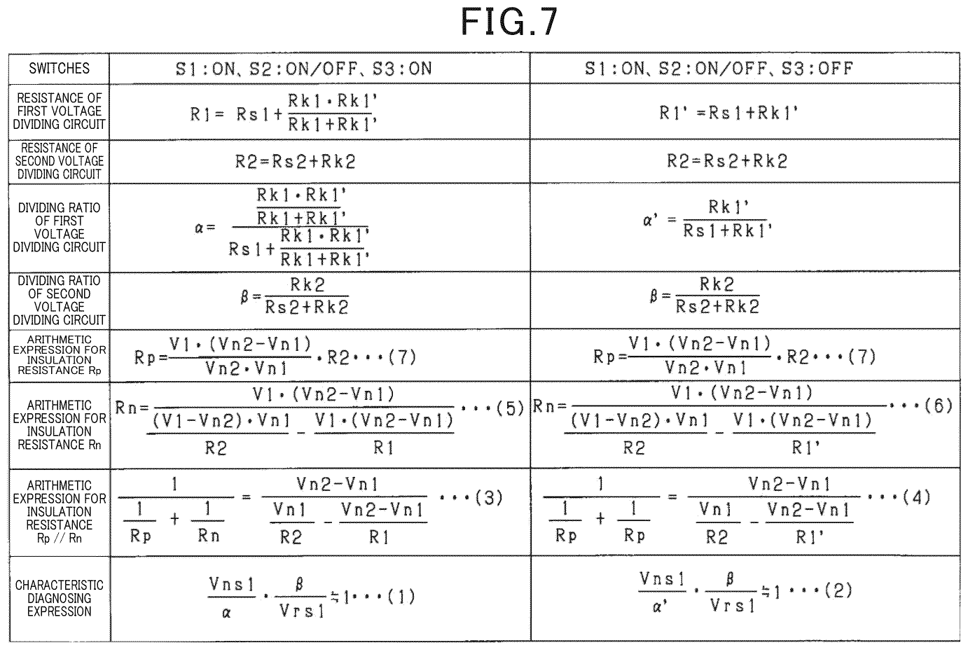

A current leakage detection process will now be described in detail with reference to FIGS. 2 to 6. In addition, FIG. 7 illustrates arithmetic expressions for the resistances R1 and R1′ of the first voltage dividing circuit 30, the resistance R2 of the second voltage dividing circuit 40, the voltage-dividing ratios α and α′ of the first voltage dividing circuit 30, the voltage-dividing ratio β of the second voltage dividing circuit 40, the insulation resistances Rp, Rn, and Rp//Rn, and characteristic diagnosing expressions.

In FIG. 7, the calculation method for each value when the third switch S3 is on is shown on the left, and the calculation method for each value when the third switch S3 is off is shown on the right. That is, the resistance R1 of the first voltage dividing circuit 30 is a resistance when the third switch S3 is on, and the resistance R1′ is a resistance when the third switch S3 is off. Similarly, the voltage-dividing ratio α of the first voltage dividing circuit 30 is a voltage-dividing ratio when the third switch S3 is on, and the voltage-dividing ratio α′ is a voltage-dividing ratio when the third switch S3 is off.

The characteristic diagnosing expressions are used to perform characterization to determine whether there are any abnormalities in the characteristics of the first voltage dividing circuit 30 and the second voltage dividing circuit 40. The characterization is, performed to determine, for example, whether the resistance values of the detection resistors Rs1, Rs2, Rk1, Rk1′, and Rk2 have changed due to aging, poor contact, contamination with foreign matters, broken wires, short circuits, etc.

The resistance of the first A detection resistor Rs1 is “Rs1”, the resistance of the first B detection resistor Rk1′ is “Rk1”, and the resistance of the first C detection resistor Rk1 is “Rk1”. Similarly, the resistance of the second A detection resistor Rs2 is “Rs2”, and the resistance of the second B detection resistor Rk2 is “Rk2”. The voltage across the assembled battery 10 is “V1”.

The voltage across the insulation resistance Rn corresponds to “Vni”, and the voltage across the insulation resistance Rn when the first switch S1 and the second switch S2 are on corresponds to “Vn1”. In addition, the voltage across the insulation resistance Rn when the first switch S1 is on and the second switch S2 is off corresponds to “Vn2”.

In addition, the first voltage-dividing value from the first voltage dividing circuit 30 corresponds to “Vnsi”. The first voltage-dividing value from the first voltage dividing circuit 30 when the first switch S1 and the second switch S2 are on corresponds to “Vns1”. The first voltage-dividing value from the first voltage dividing circuit 30 when the first switch S1 is on and the second switch S2 is off corresponds to “Vns2”. The first voltage-dividing value from the second voltage dividing circuit 40 when the first switch S1 and the second switch S2 are on corresponds to “Vrs1”.

The current leakage detection process illustrated in FIG. 2 is performed by the control unit 70 every predefined cycle (e.g., every several tens of milliseconds). Upon initiating the current leakage detection process, the control unit 70 first turns on all of the first through third switches S1 to S3 (at step S10). As a result, both the first voltage dividing circuit 30 and the second voltage dividing circuit 40 are energized, resulting in the first voltage dividing circuit 30, the second voltage dividing circuit 40, and the insulation resistance Rn being connected in parallel between the negative-side power supply path L2 and the vehicle-side ground FG. In the first voltage dividing circuit 30, both the first B detection resistor Rk1′ and the first C detection resistor Rk1 are energized, and the voltage voltage-dividing ratio of the first dividing circuit 30 becomes the voltage-dividing ratio α.

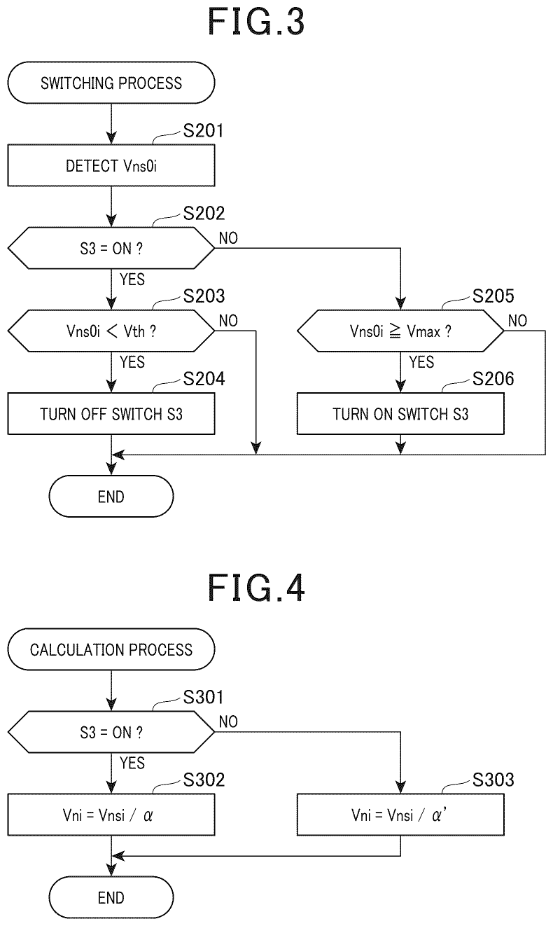

After a predefined time has elapsed, the control unit 70 performs a switching process for turning on or off the third switch S3 (at step S102). The switching process will now be described with reference to FIG. 3. In the switching process, at step S102, i should be read as 1. For example, Vns0i in FIG. 3 is read as Vns01.

In the switching process, the control unit 70 inputs (detects) the first voltage voltage-dividing value Vns0i from the first voltage dividing circuit 30 (at step S210). When the third switch S3 is on, the first voltage-dividing value Vns0i=α×Vni, and when the third switch S3 is off, the first voltage-dividing value Vns0i=α′×Vni.

Next, the control unit 70 determines whether the third switch S3 is on (at step S202). If the answer is YES at step S202, the control unit 70 determines whether the detected first voltage-dividing value Vns0i is less than the threshold value Vth (at step S203). The threshold value Vth is an arbitrary value and is set according to the resolution of the control unit 70 and the required detection accuracy.

If the answer is YES at step S203, the control unit 70 turns off the third switch S3 (at step S204). As a result, in the first voltage dividing circuit 30, the first C detection resistor Rk1 is energized and is placed in the de-energized blocked state, and the voltage voltage-dividing ratio of the first voltage dividing circuit 30 becomes the voltage voltage-dividing ratio α′. If the answer is NO at step S203, the control unit 70 terminates the switching process and proceeds to step S103.

If the answer is NO at step S202, the control unit 70 determines whether the detected first voltage-dividing value Vns0i is greater than or equal to the limit value Vmax (at step S205). The limit value Vmax is an arbitrary value and is set according to the resolution of the control unit 70, withstand voltage, detection accuracy, etc.

If the answer is YES at step S205, the control unit 70 turns on the third switch S3 (at step S206) and terminates the switching process. As a result, in the first voltage dividing circuit 30, the first C detection resistor Rk1 is energized and the voltage voltage-dividing ratio of the first voltage dividing circuit 30 becomes the voltage-dividing ratio α. If the answer is NO at step S205, the control unit 70 terminates the switching process and proceeds to step S103.

As illustrated in FIG. 2, at a predefined timing after completion of the switching process at step S102, the control unit 70 inputs (detects) the first voltage dividing value Vns1 from the first voltage dividing circuit 30 and inputs (detects) the second voltage dividing value Vrs1 from the second voltage dividing circuit 40 (at step S103). When the third switch S3 is on, the first voltage-dividing value Vns1=α×Vn1, and when the third switch S3 is off, the first voltage-dividing value Vns1=α′×Vn1. The second voltage-dividing value Vrs1=β×Vn1.

Next, the control unit 70 performs the calculation process for calculating Vn1 (at step S104). The calculation process will now be described with reference to FIG. 4. In the calculation process at step S104, i should be read as 1. For example, in FIG. 4, Vni is read as Vn1, and Vnsi is read as Vns1.

In the calculation process, the control unit 70 determines whether the third switch S3 is on (at step S301). If the answer is YES″ at step 301, the control unit 70 calculates Vni by calculating Vnsi/α (at step S302), and then terminates the calculation process. If the answer is NO at step S301, the control unit 70 calculates Vni by calculating Vnsi/α′ (at step S303), and then terminates the calculation process.

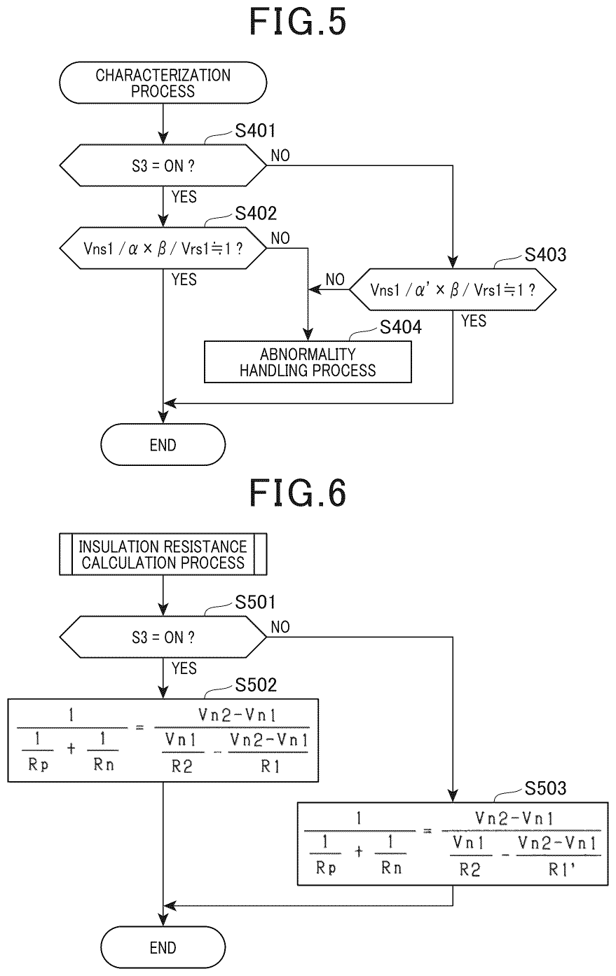

As illustrated in FIG. 2, after completion of the calculation process at step S104, the control unit 70 performs the characterization process (at step S105). The characterization process will now be described with reference to FIG. 5.

In the characterization process at step S105, the control unit 70 determines whether the third switch S3 is on (at step S401). If the answer is YES at step S401, the control unit 70 determines whether the result of arithmetic expression (1) shown in FIG. 7 is approximately 1 (at step S402). That is, as illustrated in FIG. 7, it determines whether the value of the characteristic diagnosing expression (1) ((Vns1/α)×(B/Vrs1)) when the third switch S3 is on is within a predefined range close to 1. The predefined range is set taking into account the calculation accuracy. If the value in this case is within the predefined range close to 1, it is determined that there is no abnormality, and if the value is not within the predefined range, it is determined that there is an abnormality.

If the answer is NO at step S401, the control unit 70 determines whether the result of the arithmetic expression (2) shown in FIG. 7 is about 1 (at step S403), as in step S402. That is, as illustrated in FIG. 7, it determines whether the value of the characteristic diagnosing formula (arithmetic expression (2)) ((Vns1/α′)×(B/Vrs1)) when the third switch S3 is off is within a predefined range close to 1. The predefined range is set taking into account the calculation accuracy. If the value in this case is within the predefined range close to 1, it is determined that there is no abnormality, and if the value is not within the predefined range, it is determined that there is an abnormality.

If the answer is YES at step S402 or step S403, it is determined that there is no characteristic abnormality, and the control unit 70 terminates the characterization process and proceeds to the next step S106. If the answer is NO at step S402 or step S403, it is determined that there is a characterization abnormality in the first voltage dividing circuit 30 or the second voltage dividing circuit 40, and the control unit 70 suspends the current leakage determination process and performs a process for handling the abnormality in the voltage dividing circuits 30, 40 (at step S404). The process for handling the abnormalities in the voltage dividing circuits 30 and 40 is, for example, a process for notifying an external device of the abnormality and warning it that current leakage detection is not possible.

As illustrated in FIG. 2, after the characterization process is successfully completed, the control unit 70 turns the second switch S2 off at the timing when the predefined time has elapsed (at step S106). Then, at the timing when the predefined time has elapsed, the control unit 70 performs the switching process for the third switch S3 (at step S107). The switching process at step S107 is the same as described above by reading i as i=2 in the description of the switching process at step S102 and FIG. 3. For example, the same as described above if Vns0i is read as Vns02. Thus, the description will be omitted here.

As illustrated in FIG. 2, after completion of the switching process at step S107, the control unit 70 inputs (detects) the first voltage dividing value Vns2 from the first voltage dividing circuit 30 (at step S108) at a timing when a pre-defined time has elapsed. When the third switch S3 is on, the first voltage-dividing value Vns2=α×Vn2, and when the third switch S3 is off, the first voltage-dividing value Vns2=α′×Vn2.

Next, the control unit 70 performs the calculation process for Vn2 (at step S109). The calculation process at step S109 is the same as the one described above if i is read as i=2 in the calculation process at step S104 and description about FIG. 4. For example, if Vnsi is read as Vns2 and Vni is read as Vn2, the calculation process is the same as the one described above. Thus, the description will be omitted here.

After completion of the calculation process at step S109, as illustrated in FIG. 2, the control unit 70 performs the insulation resistance calculation process (at step S110), in which insulation resistance is calculated. The insulation resistance calculation process will now be described with reference to FIG. 6.

In the insulation resistance calculation process at step S110, the control unit 70 determines whether the third switch S3 is on (at step S501). If the answer is YES at step S501, the control unit 70 calculates the insulation resistances based on Vn1 and Vn2 calculated at steps S104 and S109 (at step S502). At step S502, Rp//Rn is calculated according to the composite arithmetic expression (3) listed in FIG. 7, that is, from the composite arithmetic expression for the insulation resistances Rp and Rn when the third switch S3 is on. The insulation resistances Rp and Rn may be calculated from the arithmetic expressions (5) and (7) listed in FIG. 7, respectively.

On the other hand, if the answer is NO at step S501, the control unit 70 calculates the insulation resistances based on Vn1 and Vn2 calculated at steps S104 and S109 (at step S503). At step S503, Rp//Rn is calculated according to the arithmetic expression (4) listed in FIG. 7, that is, from the composite arithmetic expression for the insulation resistances Rp and Rn when the third switch S3 is off. The insulation resistances Rp and Rn may be calculated from the arithmetic expressions (6) and (7) listed in FIG. 7, respectively.

After completion of the insulation resistance calculation process, the control unit 70 determines whether there is a current leakage occurring based on the calculated insulation resistances (at step S111). At step S111, for example, a determination as to whether there is a current leakage occurring is made based on whether the calculated Rp//Rn are within the predefined normal range. In the case of the insulation resistances Rp and Rn being calculated, a determination as to whether there is current leakage occurring may be made based on whether the insulation resistances Rp and Rn are less than or equal to their respective threshold values Rp0 and Rn0.

If the answer is YES at step S111 (i.e., if a current leakage is detected), the control unit 70 performs a process for handling the current leakage (at step S112), and then terminates the current leakage detection process. The process for handling the current leakage is, for example, a process for notifying and warning an external device of the current leakage. On the other hand, if the answer is NO at step S112 (i.e., if there is no current leakage detected), the control unit 70 assumes that the system is normal and terminates the current leakage detection process.

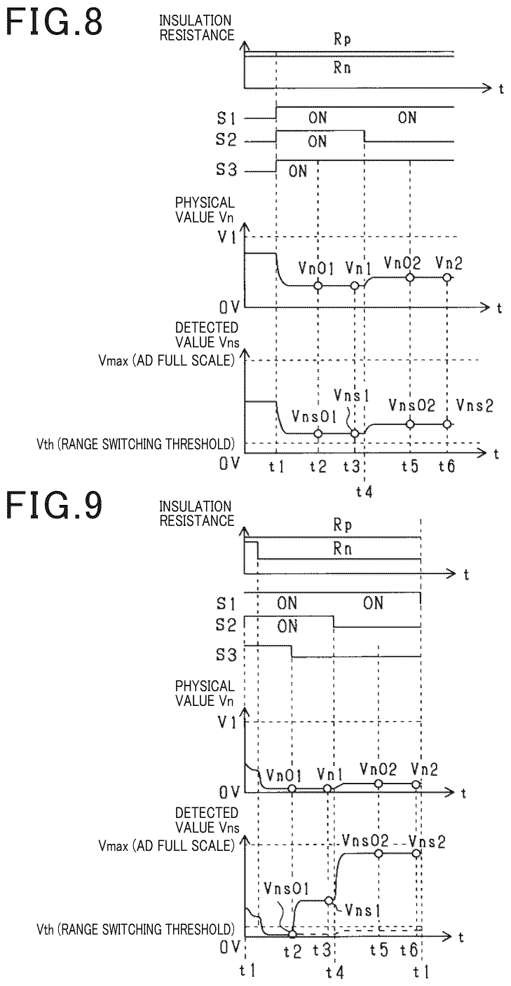

Next, detection timings of the voltage-dividing values and switching timings of the first S1 to third S3 switches will now be described with reference to FIG. 8 and FIG. 9.

FIG. 8 will now be described assuming that the insulation resistances Rp and Rn are both normal. When the first switch S1 to the third switch S3 are turned on (at time t1), both the first voltage dividing circuit 30 and the second voltage dividing circuit 40 are energized, resulting in the first voltage dividing circuit 30, the second voltage dividing circuit 40, and the insulation resistance Rn being connected in parallel between the negative-side power supply path L2 and the vehicle side ground FG. In the first voltage dividing circuit 30, both the first B detection resistor Rk1′ and the first C detection resistor Rk1 are energized, and the voltage-dividing ratio of the first voltage dividing circuit 30 becomes the voltage-dividing ratio α.

In order to stabilize the voltage-dividing value, the control unit 70 performs the switching process of the third switch S3 at the timing (at time t2) when the predefined time has elapsed. That is, the first voltage-dividing value Vns01 from the first voltage dividing circuit 30 is input, and whether the first voltage-dividing value Vns01 is less than the threshold value Vth is determined. By assumption, Since the first voltage-dividing value Vns01 is greater than or equal to the threshold Vth, the third switch S3 is not turned off (it is maintained in the on state). At a timing when a predefined time has elapsed (at t3), the control unit 70 inputs the first voltage-dividing value Vns1 and performs the calculation process for calculating Vn1. Here, because the third switch S3 is on, the control unit 70 calculates Vn1 by calculating Vns1/α.

Although not shown, at this point t3, the control unit 70 inputs the second voltage voltage-dividing value Vrs1 from the second voltage dividing circuit 40 and determines whether (Vns1/α)×(B/Vrs1) is about 1, thereby performing the characterization.

After calculating Vn1, i.e., the control unit 70 turns off the second switch S2 at a timing (at time t4) after a predefined time has elapsed. This causes the first voltage dividing circuit 30 to be placed in the energized state, while the second voltage dividing circuit 40 is placed in the de-energized state. As a result, the first voltage dividing circuit 30 and the insulation resistance Rn are connected in parallel between the negative side power supply path L2 and the vehicle side ground FG. In addition, in the first voltage dividing circuit 30, both the first B detection resistor Rk1′ and the first C detection resistor Rk1 are in the energized state, and the voltage-dividing ratio of the first voltage dividing circuit 30 becomes the voltage-dividing ratio α.

In order to stabilize the voltage-dividing value, the control unit 70 performs the switching process of the third switch S3 at a timing (at time t5) when a predefined time has elapsed. That is, the first voltage-dividing value Vns02 from the first voltage dividing circuit 30 is input, and it is determined whether the first voltage-dividing value Vns02 is less than the threshold value Vth. Since the first voltage-dividing value Vns02 is greater than or equal to the threshold value Vth from the assumption, the third switch S3 is not turned off (it is maintained in the on state). The control unit 70 then inputs the first voltage-dividing value Vns2 at a timing when a predefined time has elapsed (at time t6), and performs the calculation process for Vns2. Here, since the third switch S3 is on, the control unit 70 calculates Vn2 by calculating Vns2/α.

The control unit 70 calculates Rp//Rn from the calculated Vn1 and Vn2 using the arithmetic expression (1) listed in FIG. 7. It is determined that there is no current leakage based on whether Rp//Rn is within the normal range.

Next, FIG. 9 will now be described. In FIG. 9, it is assumed that the insulation resistance Rn is grounded after all of the first switch S1 to the third switch S3 are turned on (after time t1) and before the switching process of the third switch S3 is performed (before time t2).

Upon turning on the first switch S1 to the third switch S3 (at time t1), the first voltage dividing circuit 30 and the second voltage dividing circuit 40 are both energized. As a result, the first voltage dividing circuit 30, the second voltage dividing circuit 40, and the insulation resistance Rn are connected in parallel between the negative side power supply path L2 and the vehicle side ground FG. In addition, in the first voltage dividing circuit 30, both the first B detection resistor Rk1′ and the first C detection resistor Rk1 are in a state of current flow, and the voltage-dividing ratio of the first voltage dividing circuit 30 becomes the voltage-dividing ratio α.

In order to stabilize the voltage-dividing value, the control unit 70 executes the switching process of the third switch S3 at a timing (at time t2) when a predefined time has elapsed. That is, the first voltage-dividing value Vns01 from the first voltage dividing circuit 30 is input, and it is determined whether the first voltage-dividing value Vns01 is less than the threshold value Vth. Since the first dividing value Vns01 is less than the threshold value Vth, the third switch S3 is turned off. As a result, the first C detection resistor Rk1 is placed in the de-energized state in the first voltage dividing circuit 30, and the voltage-dividing ratio of the first voltage dividing circuit 30 becomes the voltage-dividing ratio α′. As illustrated in FIG. 9, the detected first voltage dividing value (detected voltage value) increases (by a factor of about 10). In FIG. 9, the detected voltage when the voltage-dividing ratio α of the first voltage dividing circuit 30 is unchanged is indicated by the broken line.

The control unit 70 inputs the first voltage-dividing value Vns1 at the timing when a predefined time has elapsed (at time t3) and performs the calculation process for Vn1. Here, because the third switch S3 is off, the control unit 70 calculates Vn1 by calculating Vns1/α′.

Although not shown, at this time t3, the control unit 70 inputs the second voltage voltage-dividing value Vrs1 from the second voltage dividing circuit 40 and determines whether (Vns1/α′)×(B/Vrs1) is about 1, thereby performing the characterization.

After calculating Vn1, i.e., the control unit 70 turns off the second switch S2 at a timing (at time t4) after a predefined time has elapsed. This causes the first voltage dividing circuit 30 to be placed in the energized state, while the second voltage dividing circuit 40 is placed in the de-energized state. As a result, the first voltage dividing circuit 30 and the insulation resistance Rn are connected in parallel between the negative electrode power path L2 and the vehicle side ground FG.

In order to stabilize the voltage-dividing value, the control unit 70 performs the switching process of the third switch S3 at a timing when a predefined time has elapsed (at time t5). That is, the first voltage-dividing value Vns02 from the first voltage dividing circuit 30 is input, and it is determined whether the first voltage-dividing value Vns02 is greater than or equal to a limit value Vmax. Since the first voltage-dividing value Vns02 is less than the limit value Vmax, the third switch S3 is off (it is kept off). As a result, the first voltage dividing circuit 30 keeps the first C detection resistor Rk1 in the de-energized state, and the voltage-dividing ratio of the first voltage dividing circuit 30 becomes the voltage-dividing ratio α′.

The control unit 70 then inputs the first voltage-dividing value Vns2 at a timing when a predefined time has elapsed (at time t6), and performs the calculation process for Vn2. Here, since the third switch S3 is off, the control unit 70 calculates Vn2 by calculating Vns2/α′.

The control unit 70 calculates Rp//Rn from the calculated Vn1 and Vn2 using the arithmetic expression (2) listed in FIG. 7. It then determines whether there is a current leakage based on whether Rp//Rn is within the normal range.

The effects of the embodiment described above will now be described.

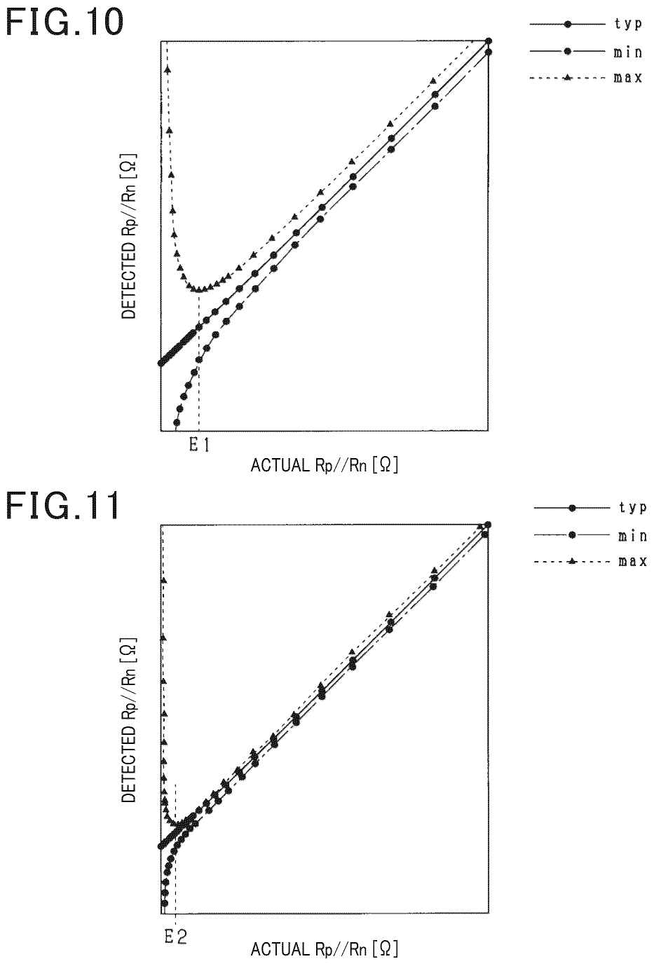

(1) Conventionally, when the insulation resistances Rp and Rn decrease, the effect of circuit tolerance may temporarily increase. For example, when the actual insulation resistance Rn decreases, the voltage across the insulation resistance Rn also decreases. As a result, the detected voltages Vn1 and Vn2 also decrease and approach zero. When Vn1 and Vn2 approach zero, the effect of circuit tolerance increases relatively. As a result, there is a possibility that Vn1 and Vn2 will become equal, or that Vn1 will become higher than Vn2, causing a reversal of the order of magnitude. As illustrated in FIG. 10, when the actual insulation resistance (actual Rp//Rn) decreases, the insulation resistance calculated from the detected voltage values (detected Rp//Rn) may diverge and become indefinite. This makes it impossible to calculate the normal insulation resistance and make a normal determination. In FIGS. 10 and 11, the ideal insulation resistance (detection Rp//Rn) is indicated by the solid line, the maximum value of the calculated insulation resistance (detection Rp//Rn) is indicated by the dashed-dotted line, and the minimum value is indicated by the dashed-dotted-dotted line.

Thereupon, when the detected first dividing values Vns01, Vns02 of the first dividing circuit 30 are less than the threshold value Vth, the control unit 70 turns off the third switch S3 and changes the voltage-dividing ratio α′ from the voltage voltage-dividing ratio α of the first dividing circuit 30 to increase the detected first dividing value, as illustrated in FIG. 9. Therefore, the resolution of the control unit 70 may be substantially reduced without changing the resolution of the control unit 70, since the first divider value can thus be increased. That is, in this case, even after the insulation resistance Rn has decreased, i.e., even in the case where the insulation resistance Rn is likely to be shorted, the effect of circuit tolerance can be suppressed and the first voltage-dividing value can be detected with high accuracy.

Specifically, as can be understood by comparing the range E1 (see FIG. 10) and the range E2 (see FIG. 11), the application of the current leakage detection device 20 described above can reduce the range where the calculated insulation resistance (detection Rp//Rn) begins to diverge. That is, even if the actual insulation resistance (actual Rp//Rn) drops considerably, the insulation resistance (detected Rp//Rn) can be calculated with high accuracy without divergence. In addition, as can be seen by comparing FIG. 10 and FIG. 11, the maximum and minimum values of the calculated insulation resistance (detection Rp//Rn) can be brought closer to the ideal values. Therefore, the accuracy of current leakage detection can be improved.

(2) The control unit 70 performs a first input step (corresponding to step S103) of inputting the first voltage dividing value Vns1 from the first voltage dividing circuit 30 when the second voltage dividing circuit 40 is in the energized state, a second input step (corresponding to step S108) of inputting the first voltage dividing value Vns2 from the first voltage dividing circuit 30 when the second voltage dividing circuit 40 is in the de-energized state, and a current leakage detection step (at steps S104, S109, S110, S111) of calculating the insulation resistance from the first voltage divider value Vns1 and the first voltage divider value Vns2 and detecting a current leakage (corresponding to steps S104, S109, S110, S111). The control unit 70 inputs the first voltage-dividing values Vns01, Vns02 from the first voltage dividing circuit 30 before the first or second input step is performed, and when the input first voltage-dividing value is less than the threshold value Vth, the third switch S3 is turned off and changed to the voltage-dividing ratio α′ of the first voltage dividing circuit 30. In this manner, since switching is performed before the detection timing, the first divider values Vns1 and Vns2 can be detected with high accuracy.

(3) In the first switching step (corresponding to step S101), the control unit 70 turns on both the first switch S1 and the second switch S2 and inputs the first voltage-dividing value Vns1 and the second voltage-dividing value Vrs1 in the first input step (corresponding to step S103). The control unit 70 then performs a characterization step (corresponding to step S105) based on the first voltage-dividing value Vns1 and the second voltage-dividing value Vrs1. Thereafter, the control unit 70 turns the second switch S2 off in the second switching step (corresponding to step S106) and inputs the first voltage-dividing value Vns2 in the second input step (corresponding to step S108).

This allows the first divider value Vns1 and the second divider value Vrs1 necessary to perform the characterization to be input, during implementation of the first and second input steps required for current leakage detection, more specifically, during implementation of the first input step. Therefore, it is no longer necessary to switch the second switch S2 and set aside time for measurement just to acquire the first and second voltage-dividing values Vns1 and Vrs1 necessary for characterization, and leakage current detection and characterization can be performed efficiently. This allows leakage current detection and characterization to be performed simultaneously, thereby making it possible to detect an abnormality in the voltage dividing circuits 30 and 40 at all times.

(4) In the characterization process, the control unit 70 changes the characteristic diagnosing formulas by turning the third switch S3 on and off. This allows the voltage-dividing ratio to be changed and the detected first dividing value to be increased, even when the insulation resistance Rn decreases, and detection accuracy to be improved. Therefore, it is possible to suppress a decrease in characterization accuracy.

(5) When detecting a current leakage by calculating the value of Rp//Rn using the arithmetic expression (3) or (4) listed in FIG. 7, it is not necessary to measure the voltage V1 across the assembled battery 10. This can eliminate the need to take into account measurement errors in the voltage V1, and improve the current leakage detection accuracy.

### Exemplary Modifications

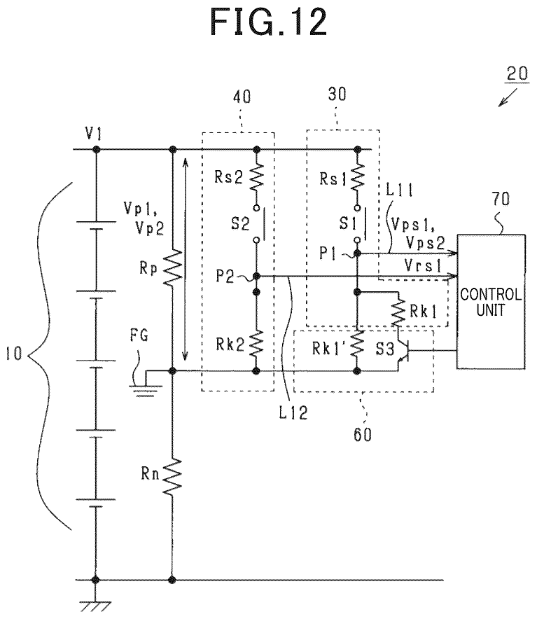

The configuration of the above embodiment may partially be modified as follows. In the following, example configurations will now be described.
In the above embodiment, the processing order of steps S104 and S109 may be changed arbitrarily as long as they are performed before step S110.
In the above embodiment, the current leakage detection device 20 is connected between the negative-side power supply path L2 and the vehicle-side ground FG. In an alternative, as illustrated in FIG. 12, the current leakage detection device 20 may be connected between the positive-side power supply path L1 and the vehicle-side ground FG. Specifically, the first voltage dividing circuit 30 according to the exemplary modification illustrated in FIG. 12 is connected between the positive-side power supply path L1 and the vehicle-side ground FG, and divides the voltage between the positive-side power supply path L1 and the vehicle-side ground FG (the voltage at both ends of the first voltage dividing circuit 30) by the voltage-dividing ratio α or the voltage-dividing ratio α′. The first A detection resistor Rs1 illustrated in FIG. 12 is connected to the positive-side power supply path L1, and the parallel connection of the first B detection resistor Rk1′ and the first C detection resistor Rk1 is connected to the vehicle-side ground FG.

The second voltage dividing circuit 40 illustrated in FIG. 12 is connected between the positive-side power supply path L1 and the vehicle-side ground FG, and divides the voltage between the positive-side power supply path L1 and the vehicle-side ground FG (the voltage at both ends of the second voltage dividing circuit 40) by the voltage-dividing ratio β. The second A detection resistor Rs2 illustrated in FIG. 12 is connected to the positive-side power supply path L1, and the second B detection resistor Rk2 is connected to the vehicle-side ground FG. The control unit 70 inputs signals from the first voltage dividing circuit 30 and the second voltage dividing circuit 40 with the vehicle side ground FG as the reference potential.

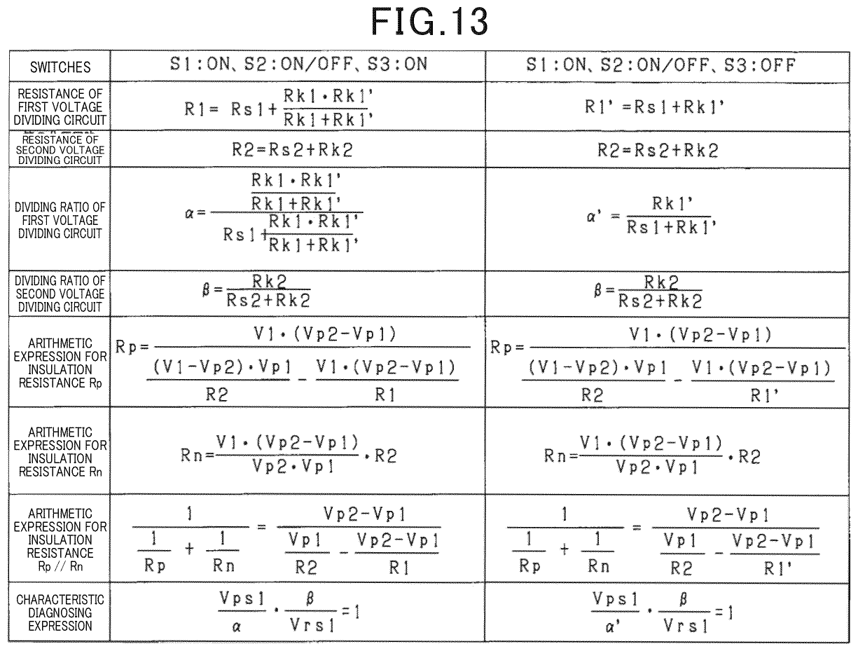

FIG. 13, as in FIG. 7, illustrates the arithmetic expressions for the resistance values R1 and R1′ of the first voltage dividing circuit 30, the resistance value R2 of the second voltage dividing circuit 40, the voltage-dividing ratios α and α′ of the first voltage dividing circuit 30, the voltage-dividing ratio β of the second voltage dividing circuit 40, the insulation resistances Rp, Rn and Rp//Rn, and the characteristic diagnosing expressions.

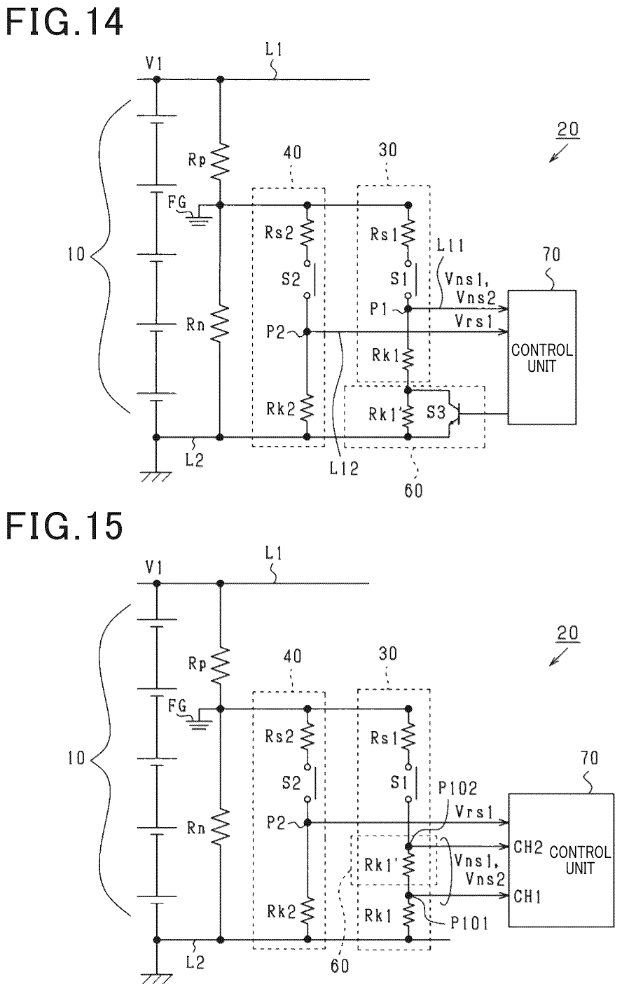

In FIG. 13, the voltage across the insulation resistance Rp corresponds to “Vpi”, and the voltage across the insulation resistance Rp when the first switch S1 and the second switch S2 are on corresponds to “Vp1”. The voltage across the insulation resistance Rp when the first switch S1 is on and the second switch S2 is off corresponds to “Vp2”. The first voltage-dividing value from the first voltage dividing circuit 30 corresponds to “Vpsi”, and the first voltage-dividing value from the first voltage dividing circuit 30 when the first switch S1 and the second switch S2 are on corresponds to “Vps1”. Otherwise, the same applies as in FIG. 7.
As illustrated in FIG. 14, the first voltage dividing circuit 30 of the above embodiment may partially be changed. Specifically, the first voltage dividing circuit 30 includes the first A detection resistor Rs1, the first C detection resistor Rk1, and the first B detection resistor Rk1′, which are connected in series. The third switch S3 is connected in parallel with the first B detection resistor Rk1′. In FIG. 14, the first B detection resistor Rk1′ and the third switch S3, which is connected in parallel with the first B detection resistor Rk1′ and serves as a voltage-dividing ratio changing switch to turn on and off the first B detection resistor Rk1′, correspond to the range change circuit 60.

A portion of the first voltage dividing circuit 30 of the above embodiment may be changed as illustrated in FIG. 15. Specifically, the first voltage dividing circuit 30 includes the first A detection resistor Rs1, the first B detection resistor Rk1′ (corresponding to the range change circuit), and the first C detection resistor Rk1, which are connected in series in this order from the vehicle side ground FG side. The control unit 70 inputs the first voltage-dividing value Vns0i, Vnsi (i=1 or 2) from the connection point P101 between the first B detection resistor Rk1′ and the first C detection resistor Rk1 during normal operation (when the insulation resistance is high). That is, the control unit 70 inputs the first voltage-dividing values Vns0i and Vnsi (i=1 or 2) from channel CH1.

Then, when the first voltage-dividing value Vns0i (i=1 or 2) input from channel CH1 is less than the threshold value Vth, the control unit 70 inputs the first voltage-dividing value Vnsi (i=1 or 2) from the connection point P102 between the first detection resistor Rs1 and the first detection resistor Rk1′. That is, the control unit 70 inputs the first voltage-dividing value Vnsi (i=1 or 2) from channel CH2. This allows the first voltage-dividing value to be input at the voltage-dividing ratio α′, and the voltage-dividing ratio of the first voltage dividing circuit 30 may be changed.

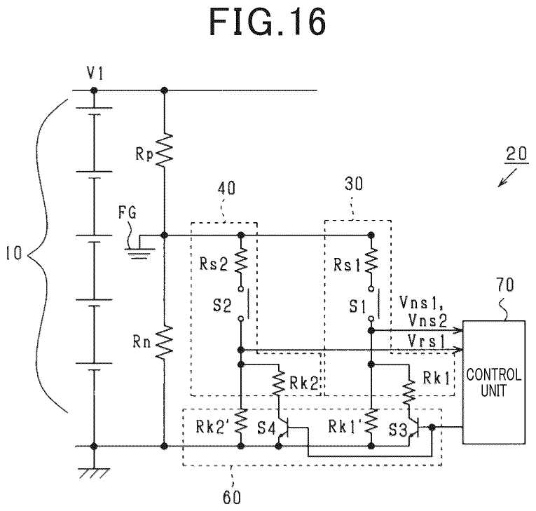

In addition, when the first voltage-dividing value Vns0i (i=1 or 2) input from channel CH2 is equal to or greater than the limit value Vmax, the first voltage-dividing value Vns0i, Vnsi (i=1 or 2) may be input from channel CH1.
In the above embodiment, a range change circuit may also be provided in the second voltage dividing circuit 40. For example, as illustrated in FIG. 16, the second voltage dividing circuit 40 includes a second A detection resistor Rs2, a second B detection resistor Rk2, a second C detection resistor Rk2′, and a fourth switch S4 as a voltage-dividing ratio changing switch.

The fourth switch S4 is connected in series with the second B detection resistor Rk2, and is used to switch between the energized state and the de-energized state of the second B detection resistor Rk2. The second A detection resistor Rs2 is connected in series with the second C detection resistor Rk2′, and the series connection of the fourth switch S4 and the second B detection resistor Rk2 is connected in parallel with the second C detection resistor Rk2′. The second C detection resistor Rk2′ and the fourth switch S4 correspond to the range changing circuit of the second voltage dividing circuit 40.

As illustrated in FIG. 16, the second voltage dividing circuit 40 is capable of changing the voltage-dividing ratio β to the voltage-dividing ratio β′ by turning on and off the fourth switch S4.

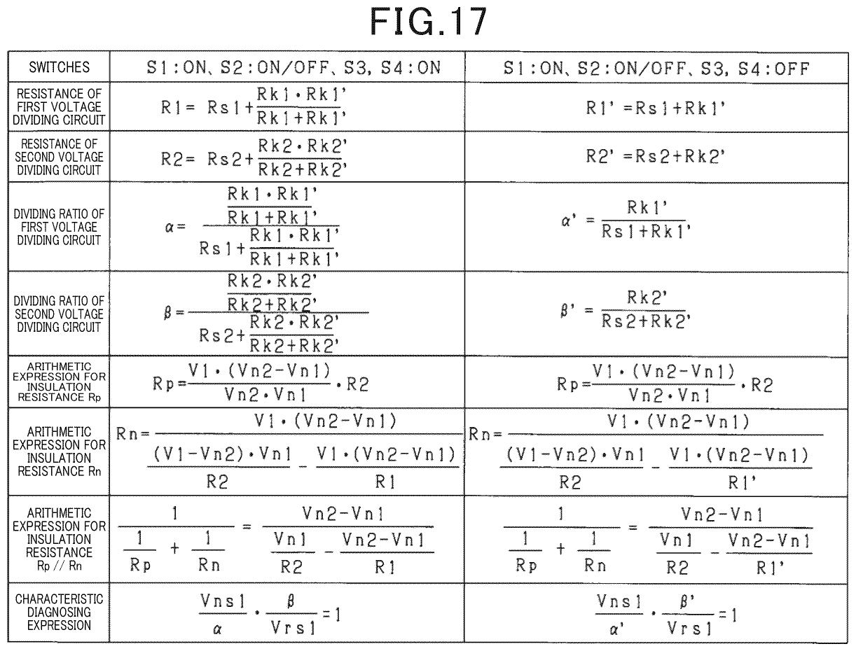

FIG. 17, as in FIG. 7, illustrates the arithmetic expressions for the resistance values R1, R1′ of the first voltage dividing circuit 30, R2, R2′ of the second voltage dividing circuit 40, the voltage-dividing ratios α, α′ of the first voltage dividing circuit 30, the voltage-dividing ratios β, B′ of the second voltage dividing circuit 40, the insulation resistances Rp, Rn, Rp//Rn, and the characteristic diagnosing expressions. In FIG. 17, the resistance value of the second C detection resistor Rk2′ is “Rk2′”. The resistance value of the second voltage dividing circuit 40 when the fourth switch is on is “R2”, and the resistance value of the second voltage dividing circuit 40 when the fourth switch is off is “R2”. This can improve the characterization accuracy.
In the current leakage detection process in the above embodiment, if the detected voltages Vn1 and Vn2 calculated at step S104 and step S109 are sufficiently low, a process may be added to suppress the effect of circuit tolerances and other

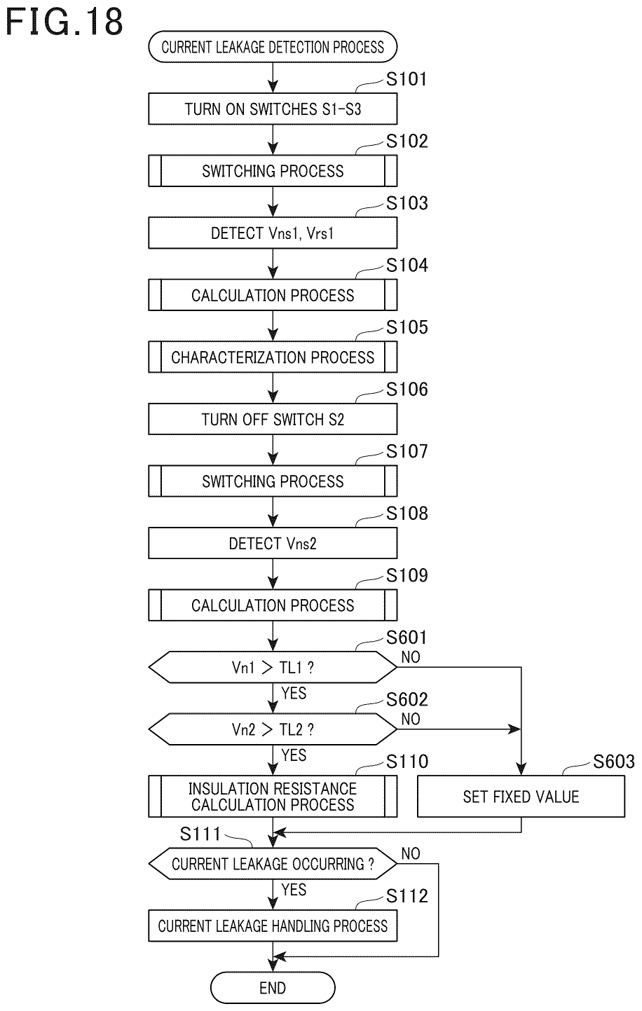

FIG. 18 will now be described. After completion of step S109, the control unit 70 determines whether the calculated detected voltage Vn1 is higher than a first threshold TL1 (at step S601). The first threshold TL1 is set to an arbitrary value taking into account, for example, circuit tolerances. For example, as illustrated in FIG. 11, the voltage value at the time when the maximum value of Rp//Rn begins to diverge (the timing indicated by the range E2) is set as the first threshold TL1.

If the answer is YES, that is, if the calculated detected voltage Vn1 is higher than the first threshold value TL1, the control unit 70 determines whether the calculated detected voltage Vn2 is higher than a second threshold value TL2 (at step S602). The second threshold value TL2 is set to an arbitrary value taking into account, for example, circuit tolerances. The first threshold TL1 and the second threshold TL2 may be the same or different values.

If the answer is YES at step S602, the control unit 70 considers that accurate characterization is possible based on the value of Rp//Rn calculated according to arithmetic expression (3), and thus performs step S110 and subsequent steps in the same manner as in the first embodiment.

On the other hand, if the answer is NO at step S601 or step S602, the control unit 70 sets the value of Rp//Rn to a fixed value (at step S603). The fixed value is a value indicating that there is a current leakage, and is determined according to the required specification of the insulation resistances Rp and Rn. For example, the fixed value is set to 4 kQ.

After step S603, the control unit 70 performs step S110 to perform current leakage detection. If a fixed value is set at step S603, it is always determined that there is a current leakage.

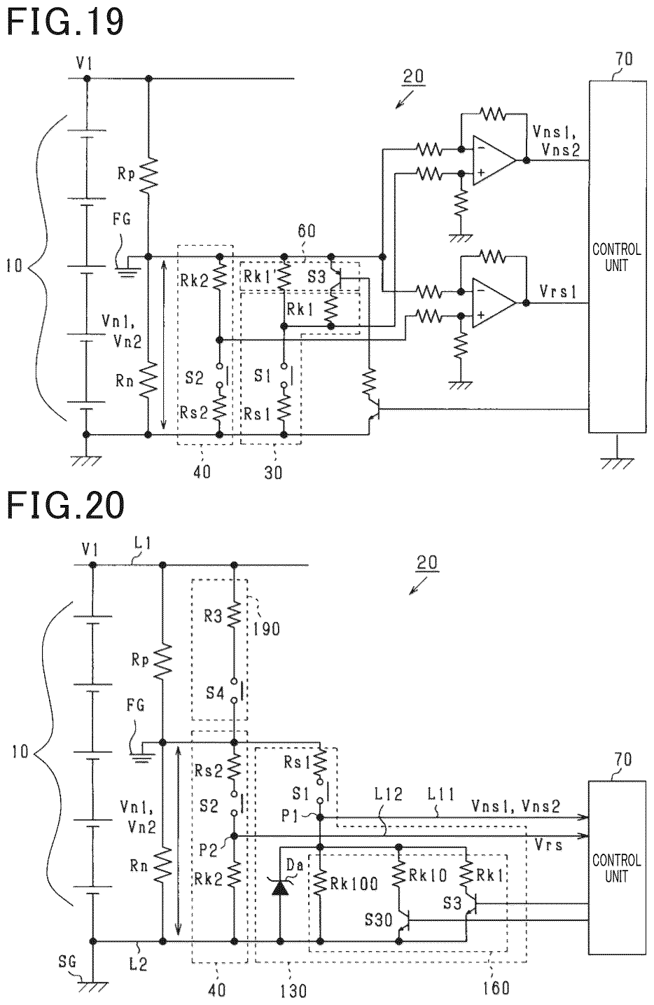

As described above, when the insulation resistances Rp and Rn decrease and the detected voltages Vn1 and Vn2 approach zero, the effect of circuit tolerances and other factors becomes significant, causing the value of the composite arithmetic expression for the insulation resistances Rp and Rn to become indefinite. In this case, when the detected voltage Vn1 is lower than or equal to the first threshold TL1, or when the detected voltage Vn2 is lower than or equal to the second threshold TL2, it is determined that there is a current leakage without calculating the value of the composite arithmetic expression for the insulation resistances Rp and Rn. This enables accurate current leakage detection without being affected by circuit tolerances.
A portion of the first voltage dividing circuit 30 in the above embodiment may be changed as illustrated in FIG. 19. That is, in the first voltage dividing circuit 30, the first A detection resistor Rs1 may be disposed on the negative-side power supply path L2 side, and the parallel connection of the first B detection resistor Rk1′ and the first C detection resistor Rk1 may be disposed on the vehicle-side ground FG side. Similarly, in the second voltage dividing circuit 40, the second A detection resistor Rs2 may be disposed on the negative-side power supply path L2 side and the second B detection resistor Rk2 may be disposed on the vehicle-side ground FG side. In this case, it is necessary to detect a voltage between the vehicle side ground FG and the connection point via a differential amplifier circuit.
In the above embodiment, the control unit 70 performs the current leakage detection process and the current leakage handling process. In an alternative, these processes may be performed by an external device. In this case, the control unit 70 may calculate and transmit the insulation resistances Rp and Rn.
In the above embodiment, the third switch S3 may be a bipolar switch (semiconductor switch) such as a transistor, or a mechanical relay.
In the above embodiment, the range change circuit 60 is configured with a single stage, and is capable of changing the voltage-dividing ratio in one step. In an alternative, the range change circuit 60 may be configured with multiple stages, and may be capable of changing the voltage-dividing ratio in multiple steps.
In the above embodiment, the second voltage dividing circuit 40 may be changed to a simple resistor in a case where the characterization is not performed.

### SECOND EMBODIMENT

A second embodiment, where the configuration of the first embodiment is partially modified, will now be described.

As described in the first embodiment, one of the causes of the first voltage-dividing value becoming smaller is that the insulation resistance Rn becomes lower, but there are other possible causes of the first voltage-dividing value becoming smaller. For example, one of the causes of the first voltage-dividing value becoming smaller is that the insulation resistance (in the first embodiment, the positive side insulation resistance Rp) that is not connected in parallel with the first voltage dividing circuit 30 becomes too high. Since this insulation resistance is a resistance on the vehicle side, it is difficult to determine the maximum value according to the specification. In particular, when the relay switches for the power supply paths L1 and L2 are turned off and the current between the electrical load, such as the rotating electric machine, and the assembled battery 10 is blocked, the insulation resistances Rn and Rp become almost infinite, so the first voltage-dividing value may become less than expected, no matter how large the voltage-dividing ratio is.

In view of the above, in the second embodiment, the following schemes are adopted such the first voltage-dividing value may be kept within an appropriate range even when the insulation resistance (in the second embodiment, the positive side insulation resistance Rp) that is not connected in parallel with the first voltage dividing circuit 30 has increased. In the second embodiment, in addition to this device, the range change circuit 60 is configured to consist of multiple stages, and the voltage-dividing ratio is configured to be changeable in multiple steps. This will now be described in detail.

First, the circuit configuration of the second embodiment will now be described. The same elements as in the first embodiment are assigned the same reference symbols, but their description will be omitted. As illustrated in FIG. 20, the first voltage dividing circuit 130 of the second embodiment is connected between the vehicle side ground FG and the negative side power supply path L2, and divides the voltage (voltage across the first voltage dividing circuit 130) between the negative side power supply path L2 and the vehicle side ground FG by a voltage-dividing ratio α, or by a voltage-dividing ratio α10, or by a voltage-dividing ratio α100. In the second embodiment, theside power supply path L2 corresponds to the first power supply path, and the positive-side power supply path L1 corresponds to the second power supply path.

Describing the configuration of the first voltage dividing circuit 130 in detail, the first voltage dividing circuit 130 includes a first A detection resistor Rs1 and a range change circuit 160. The range change circuit 160 includes a first B detection resistor Rk1, a first C detection resistor Rk10, and a first D detection resistor Rk100. The first B detection resistor Rk1, the first C detection resistor Rk10, and the first D detection resistor Rk100 are connected in parallel with each other.

More specifically, a third switch S3 is connected in series with the first B detection resistor Rk1, and the third switch S3 is configured to switch between energized and de-energized states. The 30th switch S30 is connected in series with the first C detection resistor Rk10 and is configured to switch between energized and de-energized states. The first D detection resistor Rk100 is connected in parallel with the series connection of the first B detection resistive element Rk1 and the third switch S3, and the series connection of the first C detection resistive element Rk10 and the 30th switch S30. This parallel connection corresponds to the range change circuit 160.

The range change circuit 160 is connected in series with the first A detection resistor Rs1. A Zener diode Da is connected in parallel with this range change circuit 160. The anode of the Zener diode Da is connected to the negative-terminal side power supply path L2.

The first A detection resistor Rs1 is connected to the vehicle side ground FG, and the range change circuit 160 is connected to the negative-terminal side power supply path L2. One end of the first output line L11 is connected to a first connection point P1 between the first A detection resistor Rs1 and the range change circuit 160. A voltage signal (first voltage-dividing value) from the first voltage dividing circuit 130 is output via the first output line L11.

When the third switch S3 and the 30th switch S30 are turned on, the first B detection resistor Rk1, the first C detection resistor Rk10, and the first D detection resistor Rk100 are energized and the voltage-dividing ratio of the first dividing circuit 130 is a.

When the third switch S3 is turned off and the 30th switch S30 is turned on, the first B detection resistor Rk1 is de-energized, the first C detection resistor Rk10 and the first D detection resistor Rk100 are energized and the voltage voltage-dividing ratio of the first dividing circuit 130 is a10.

When the third switch S3 and the 30th switch S30 are turned off, the first B detection resistor Rk1 and the first C detection resistor Rk10 are de-energized, the first D detection resistor Rk100 is energized and the voltage voltage-dividing ratio of the first dividing circuit 130 is a100.

The third switch S3 and the 30th switch S30 are controlled to turn on and off by the control unit 70. The resistance value of the first C detection resistor Rk10 is much higher than the resistance value of the first B detection resistor Rk1, for example, about 10 times the resistance value of the first B detection resistor Rk1. Similarly, the resistance value of the first D detected resistor Rk100 is much higher than that of the first C detected resistor Rk10, for example, about 10 times the resistance value of the first C detected resistor Rk10.

Thus, the voltage-dividing ratio α10 is greater than the voltage-dividing ratio α, and the voltage-dividing ratio α100 is greater than the voltage-dividing ratio α10 (α<α10<α100). The greater the voltage-dividing ratio, the greater the first voltage-dividing value (voltage signal) in proportion. In the second embodiment, the voltage-dividing ratio α10 is about 10 times the voltage-dividing ratio α, and the voltage-dividing ratio α100 is about 10 times the voltage-dividing ratio α10 (that is, 100 times the voltage-dividing ratio α).

As illustrated in FIG. 20, in the second embodiment, a bypass circuit 190 is provided between the positive-side power supply path L1 and the vehicle-side ground FG, which is a series connection of a resistor R3 and a fourth switch S4. The fourth switch S4 is configured to be turned on and off by the control unit 70. When the fourth switch S4 is turned on, the positive-side power supply path L1 and the vehicle-side ground FG are energized through the resistor R3. When the fourth switch S4 is turned off, the bypass circuit 190 is de-energized, and no current flows between the positive-side power supply path L1 and the vehicle-side ground FG through the resistor R3.

The resistance value of the resistor R3 is less than the positive-side insulation resistance Rp between the positive-side power supply path L1 and the vehicle-side ground FG, and is greater than a value allowed as the normal value of the insulation resistance Rp.

As illustrated in FIG. 20, this bypass circuit 190 will be connected in parallel with the positive-side insulation resistance Rp. Therefore, no matter how high the positive-side insulation resistance Rp becomes, it will not be substantially larger due to the resistor R3 connected in parallel with it. That is, when the fourth switch S4 is turned on, the potential of the vehicle side ground FG is raised toward the positive-side potential of the assembled battery 10 (positive-side power supply path L1).

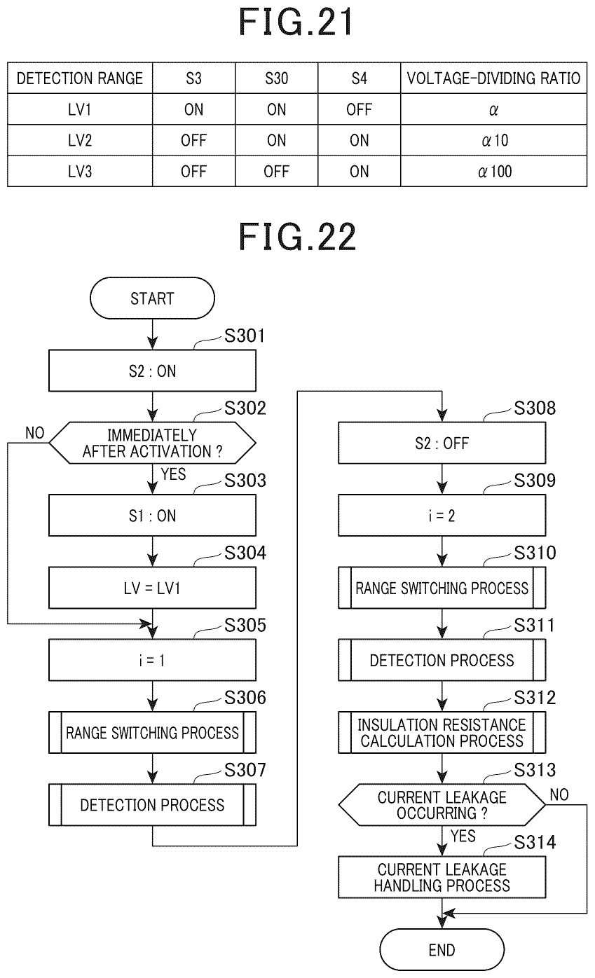

The control unit 70 of the second embodiment is capable of changing the detection range of the first voltage-dividing value in three steps by turning on/off the switches S3, S30, and S4 described above. Specifically, as illustrated in FIG. 21, in the case of a detection range LV1, the third switch S3 and the 30th switch S30 are turned on to acquire the first voltage-dividing value with the voltage-dividing ratio α. In this case, since the fourth switch S4 is off, the potential of the vehicle side ground FG will not be raised. Thus, in the case of detection range LV1, an unexpectedly high value of positive-side insulation resistance Rp may wield the effect.

In the case of a detection range LV2, the third switch S3 is turned off while the 30th switch S30 is turned on to acquire the first voltage-dividing value with the voltage-dividing ratio α10. In this case, since the fourth switch S4 is on, the potential of the vehicle side ground FG is raised. Therefore, in the case of the detection range LV2, even when the positive side insulation resistance Rp has an increased value, the effect can be substantially suppressed.

Similarly, in the case of a detection range LV3, the third switch S3 and the 30th switch S30 are turned off to acquire the first voltage-dividing value with the voltage-dividing ratio α100. In this case, since the fourth switch S4 is on, the potential of the vehicle side ground FG is raised. Therefore, in the case of the detection range LV3, even when the positive side insulation resistance Rp has an increased value, the effect can be substantially suppressed.

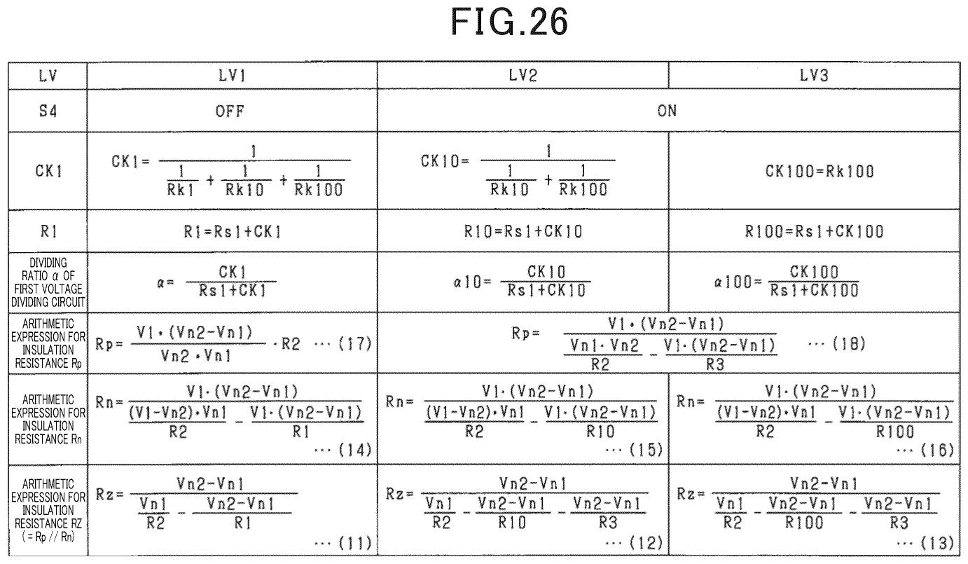

The current leakage detection process according to the second embodiment will now be described in detail with reference to FIGS. 22 to 26. FIG. 26 illustrates the arithmetic expressions for the resistance values CK1, CK10, CK100 of the range change circuit 160, the resistance values R1, R10, R100 of the first voltage dividing circuit 130, the resistance value R2 of the second voltage dividing circuit 40, the voltage-dividing ratios α, α10, α100 of the first voltage dividing circuit 130, and the voltage-dividing ratio β of the second voltage dividing circuit 40, as well as the insulation resistances Rp, Rn, Rz (=Rp//Rn). FIG. 26 lists these values for each of the detection ranges LV1 to LV3.

The resistance value of the first A detection resistor Rs1 is “Rs1”, the resistance value of the first B detection resistor Rk1 is “Rk1”, the resistance value of the first C detection resistor Rk10 is “Rk10”, and the resistance value of the first D detection resistor Rk100 is “Rk100”. The resistance value of the resistor R3 is “R3”.

In the case of the detection range is LV1, the resistance value (composite resistance value) of the range change circuit 160 is “CK1”. In the case of the detection range is LV2, the resistance value of the range change circuit 160 is “CK10”. In the case of the detection range is LV3, the resistance value of the range change circuit 160 is “CK100”. The other values are the same as in the first embodiment, so reference should be made to the first embodiment, and the description thereof will be omitted.

The current leakage detection process illustrated in FIG. 2 is performed by the control unit 70 every predefined cycle (e.g., every several tens of milliseconds). Upon initiating the current leakage detection process, the control unit 70 first turns on all of the first through third switches S1 to S3 (at step S301).

Next, the control unit 70 determines whether it is immediately after activation (e.g., immediately after an ignition switch is turned on) (at step S302). If the answer is YES, the control unit 70 turns on the first switch S1 (at step S303) and sets the detection range to “LV1” (at step S304). When setting the detection range, the control unit 70 turns on or off each of the switches S3, S30, and S4 according to the set detection range LV1 to LV3, as illustrated in FIG. 21. When the detection range is set to LV1, the voltage-dividing ratio of the first voltage dividing circuit 130 is the voltage-dividing ratio α.

After completion of step S304 or if the answer at step S302 is NO, the control unit 70 sets i=1 after a predefined time has elapsed (at step S305).

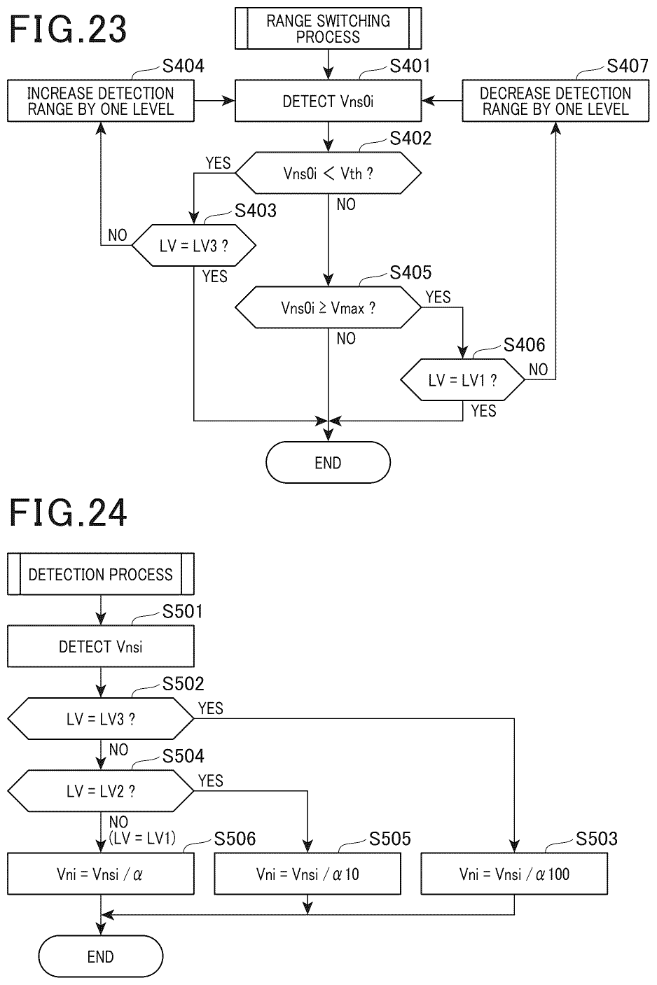

The control unit 70 performs a range switching process for switching the detection range (at step S306). The range switching process at step S306 will now be described with reference to FIG. 23. In the range switching process at step S306, i should be read as 1. For example, Vns0i in FIG. 23 is read as Vns01.

In the range switching process in FIG. 23, the control unit 70 inputs (detects) the first voltage-dividing value Vns0i from the first voltage dividing circuit 130 (at step S401). In the case of the detection range LV1, the first voltage-dividing value Vns0i=α×Vni. In the case of the detection range LV2, the first voltage-dividing value Vns0i=α10×Vni. In the case of the detection range LV3, the first voltage-dividing value Vns0i=α100×Vni.

Next, the control unit 70 determines whether the detected first voltage-dividing value Vns0i is less than a threshold value Vth (at step S402). The threshold value Vth is an arbitrary value, and is set according to the resolution, the required detection accuracy or the like of the control unit 70.

If the answer is YES at step 402, the control unit 70 determines whether the currently set detection range is the detection range LV3 (at step 403). If the answer is YES, there is no way to raise the detection range any further. Therefore, the control unit 70 terminates the range switching process. On the other hand, if the answer is NO at step S403, the control unit 70 increases the detection range by one level (at step S404). For example, if the currently set detection range is the detection range LV1, it is set to the detection range LV2. If the currently set detection range is the detection range LV2, it is set to the detection range LV3. The control unit 70 turns on or off each of the switches S3, S30, and S4 according to the updated detection range LV2 to LV3, as illustrated in FIG. 21. The control unit 70 then performs step S401 again.

On the other hand, if the answer is NO at step S402, that is, if the detected first voltage-dividing value Vns0i is greater than or equal to the threshold value Vth, the control unit 70 determines whether the detected first voltage-dividing value Vns0i is greater than or equal to a limit value Vmax (at step S405). The limit value Vmax is an arbitrary value, and is set according to the resolution, the withstand voltage, the detection accuracy or the like of the control unit 70. If the answer is NO at step S405, the control unit 70 terminates the range switching process.

If the answer is YES at step S405, the control unit 70 determines whether the currently set detection range is the detection range LV1 (at step S406). If the answer is YES, there is no way to lower the detection range. Therefore, the control unit 70 terminates the range switching process. On the other hand, if the answer is NO at step S406, the control unit 70 decreases the detection range setting by one level (at step S407). For example, if the currently set detection range is the detection range LV3, it is set to the detection range LV2. If the currently set detection range is the detection range LV2, it is set to the detection range LV1. The control unit 70 then turns on or off each of the switches S3, S30, and S4 according to the changed detection range LV1 to LV2, as illustrated in FIG. 21. The control unit 70 then performs step S401 again.

As illustrated in FIG. 22, after completion of the range switching process at step S306, the control unit 70 performs a detection process for Vn1 at a timing when a predefined time has elapsed (at step S307). The detection process for Vn1 will now be described with reference to FIG. 24. In the detection process at step S307, i should be read as 1. For example, in FIG. 24, Vni is read as Vn1, and Vnsi is read as Vns1.

As illustrated in FIG. 24, upon initiating the detection process, the control unit 70 inputs (detects) the first voltage-dividing value Vnsi from the first voltage dividing circuit 130 (at step S501). Next, the control unit 70 determines whether the currently set detection range is the detection range LV3 (at step S502). If the answer is YES, the control unit 70 calculates Vnsi/α100 and calculates Vni (at step S503). The detection process is then terminated.

On the other hand, if the answer at step S502 is NO, the control unit 70 determines whether the currently set detection range is the detection range LV2 (at step S504). If the answer is YES, the control unit 70 calculates Vnsi/α10 and calculates Vni (step S505). Then, the detection process is terminated.

On the other hand, if the answer at step S504 is NO, that is, if the detection range currently being set is the detection range LV1, the control unit 70 calculates Vnsi/α and calculates Vni (step S506). The detection process is then terminated.

As illustrated in FIG. 22, the control unit 70 turns the second switch S2 off (at step S308) at a timing when a predefined time has elapsed after completion of the detection process at step S307. The control unit 70 then sets i=2, at the timing when the predefined time has elapsed (at step S309).

The control unit 70 performs the range switching process (at step S10). The range switching process at step S310 is the same as described above, provided that i is read as 2 in the description of the range switching process at step S306 and FIG. 23. For example, reading Vns0i as Vns02, the range switching process is the same as described above. Thus, the description thereof will be omitted here.

As illustrated in FIG. 22, at a timing when a predefined time has elapsed after completion of the range switching process at step S310, the control unit 70 performs the detection process for Vn2 (at step S311). The detection process at step S311 is the same as described above in the description about the detection process at step S307 and FIG. 24, provided that i is read as 2. For example, reading Vnsi as Vns2 and Vni as Vn2, the detection process is the same as described above. Thus, the description thereof will be omitted here.

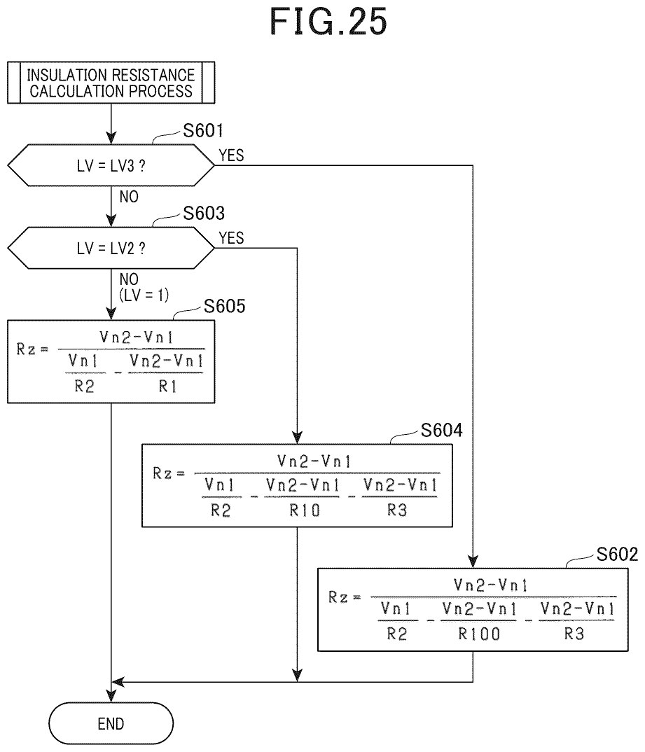

After completion of the detection process at step S311, as illustrated in FIG. 22, the control unit 70 performs an insulation resistance calculation process (at step S312) to calculate the insulation resistances. The insulation resistance calculation process will now be described with reference to FIG. 25.

In the insulation resistance calculation process at step S312, the control unit 70 determines whether the detection range currently set is the detection range LV3 (at step S601). If the answer is YES, the control unit 70 calculates the insulation resistance based on the detected Vn1 and Vn2 (at step S602). At step S602, the insulation resistance Rz when the detection range is LV3 is calculated with reference to the arithmetic expression (13) listed in FIG. 26. The insulation resistances Rp and Rn may be calculated from arithmetic expressions (16) and (18) listed in FIG. 26, respectively. Then, the insulation resistance calculation process is terminated.

On the other hand, if the answer is NO at step S601, the control unit 70 determines whether the detection range currently set is the detection range LV2 (at step S603). If the answer is YES at step 17, the control unit 70 calculates the insulation resistances based on the detected Vn1 and Vn2 (at step S604)). At step S604, the insulation resistance Rz when the detection range is LV2 is calculated with reference to the arithmetic expression (12) listed in FIG. 26. The insulation resistances Rp and Rn may be calculated from the arithmetic expressions (15) and (18) listed in FIG. 26, respectively. Then, the insulation resistance calculation process is terminated.

On the other hand, if the answer is NO at step S603, that is, if the detection range currently set is the detection range LV1, the control unit 70 calculates the insulation resistance based on the detected Vn1 and Vn2 (at step S605). At step S605, the insulation resistance Rz when the detection range is LV1 is calculated with reference to the arithmetic expression (11) listed in FIG. 26. The insulation resistances Rp and Rn may be calculated from the arithmetic expressions (14) and (17) listed in FIG. 26, respectively. Then, the insulation resistance calculation process is terminated.

As illustrated in FIG. 22, after completion of the insulation resistance calculation process, the control unit 70 determines whether a current leakage is occurring based on the calculated insulation resistance (at step S313). At step S313, for example, whether a current leakage is occurring is determined based on whether the calculated insulation resistance Rz is within a predefined normal range. Alternatively, in the case of the insulation resistances Rp and Rn being calculated, whether a current leakage is occurring may be determined based on whether they are respectively less than or equal to the threshold values for determination, Rp0 and Rn0.

If the answer at step S313 is YES (if a current leakage is detected), the control unit 70 performs a process for handling the current leakage (at step S314), and then terminates the current leakage detection process. The process for handling the current leakage includes, for example, notifying an external device of the current leakage and warning the external device. On the other hand, if the answer at step S313 is No (if no current leakage is detected), the control unit 70 assumes that the system is normal and terminates the current leakage detection process.

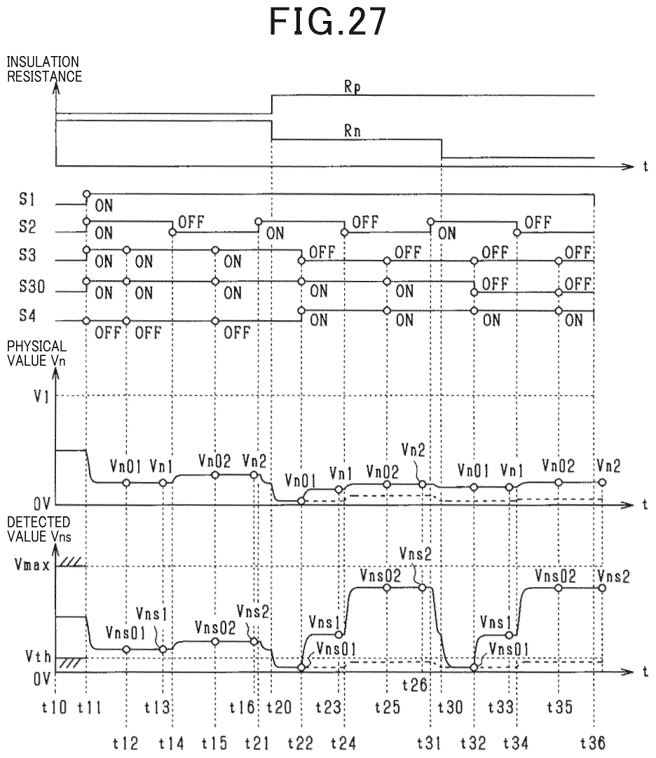

Next, the detection timing of the first voltage-dividing value and the switching timing of the detection range LV1 to L3 will now be described with reference to FIG. 27. FIG. 27 will now be described on the assumption that, initially (at time t10), both insulation resistors Rp and Rn are normal and that the detection range is being set to LV1. In the case of the detection range LV1, the switches S1, S2, S3, and S30 are turned on and the fourth switch S4 is turned off (at time t11). As a result, the voltage voltage-dividing ratio of the first voltage dividing circuit 130 becomes the voltage-dividing ratio α. Since the fourth switch S4 is off, the potential of the vehicle side ground FG is not raised.

In order to stabilize the first voltage-dividing value, the control unit 70 performs the range switching process at the timing when the predefined time has elapsed (at time t12). That is, it inputs the first voltage-dividing value Vns01 from the first voltage dividing circuit 130 and determines whether the first voltage-dividing value Vns01 is greater than or equal to the first threshold Vth and less than the limit value Vmax. From the premise, since the first voltage-dividing value Vns01 is greater than or equal to the threshold value Vth and less than the limit value Vmax, the detection range LV1 is left unchanged. At the timing when a predefined time has elapsed from then (point t13), the control unit 70 inputs the first voltage-dividing value Vns1 and calculates Vn1.

The control unit 70 turns off the second switch S2 at the timing when the predefined time has elapsed after calculating Vn1 (at time t14). In order to stabilize the voltage-dividing value, the control unit 70 performs the range switching process at the timing when the predefined time has elapsed (at time t15). That is, it inputs the first voltage-dividing value Vns02 from the first voltage dividing circuit 130 and determines whether the first voltage-dividing value Vns02 is greater than or equal to the first threshold Vth and less than the limit value Vmax. From the assumption, since the first voltage-dividing value Vns02 is greater than or equal to the threshold value Vth and less than the limit value Vmax, the detection range LV1 is left unchanged.

The control unit 70 then inputs the first voltage-dividing value Vns2 at the timing (at time t16) when the predefined time has elapsed, and calculates Vn2. The control unit 70 calculates the insulation resistance Rz from the calculated Vn1 and Vn2 using the arithmetic expression (11) listed in FIG. 26, and determines whether there is current leakage.

At time t21, after the predefined time has elapsed, the second switch S2 is turned on. The following will now be described on the assumption that, between time t21 and time t22, the first voltage-dividing value is less than the threshold value Vth in the detection range LV1 after time t20. That is, at time t20, to detect the first voltage-dividing value in the detection range LV1, assuming that the insulation resistance Rp has increased or the insulation resistance Rn has decreased.

The control unit 70 performs the range switching process at the timing when the predefined time has elapsed from time t21 (at time t22). That is, the first voltage-dividing value Vns01 from the first voltage dividing circuit 130 is input, and it is determined whether the first voltage-dividing value Vns01 is greater than or equal to the threshold value Vth and less than the limit value Vmax. Since the first voltage-dividing value Vns01 is less than the threshold value Vth, the detection range is set to LV2. As a result, the third switch S3 is turned off and the voltage-dividing ratio is changed to α10. In the row for the detected value Vns in FIG. 27, the detected voltage in the case where the voltage-dividing ratio α is fixed is indicated by the broken line. In addition, the fourth switch S4 is turned on, and the potential of the vehicle side ground FG is raised. In the column for the physical value Vn in FIG. 27, the voltage (potential) in the case where the fourth switch S4 remains off is indicated by the broken line.

The control unit 70 then inputs the first voltage-dividing value Vns1 and calculates Vn1 at a timing (at time t23) after a predefined time has elapsed. After calculating Vn1, the control unit 70 turns off the second switch S2 at a timing (at time t24) after a predefined time has elapsed. In order to stabilize the voltage-dividing value, the control unit 70 performs the range switching process at a timing when the predefined time has elapsed (at time t25). That is, the first voltage-dividing value VnS02 from the first voltage dividing circuit 130 is input, and it is determined whether the first voltage-dividing value VnS02 is greater than or equal to the threshold value Vth and less than the limit value Vmax. Since the first voltage-dividing value Vns02 is greater than or equal to the threshold value Vth and less than the limit value Vmax, the detection range remains at LV2.

The control unit 70 inputs the first voltage-dividing value Vns2 at the timing when the predefined time has elapsed since then (at time t26) and calculates Vn2. The control unit 70 calculates the insulation resistance Rz using the arithmetic expression (12) listed in FIG. 26, based on the calculated Vn1 and Vn2, and determines whether there is a current leakage.

At time t31, after the predefined time has elapsed, the second switch S2 is turned on. The following will now be described on the assumption that, after time t30 between time t31 and time t32, the first voltage-dividing value is less than the threshold value Vth in the detection range LV2. That is, the following will now be described on the assumption that the voltage-dividing ratio is not appropriate in the detection range LV2, either because the insulation resistance Rp becomes even higher or the insulation resistance Rn becomes even lower at time t30.

The control unit 70 performs the range switching process at the timing when the predefined time has elapsed from time t31 (at time t32). That is, the first voltage-dividing value Vns01 from the first voltage dividing circuit 130 is input, and it is determined whether the first voltage-dividing value Vns01 is greater than or equal to the threshold value Vth and less than the limit value Vmax. Since the first dividing value Vns01 is less than the threshold value Vth, the detection range is set to LV3. Therefore, the voltage-dividing ratio is changed to α100. In the row for the detected value Vns in FIG. 27, the detected voltage when the voltage-dividing ratio is α10 is indicated by the broken line. In addition, the fourth switch S4 is turned on, and the potential of the vehicle side ground FG is raised. In the row for the physical value Vn in FIG. 27, the voltage (potential) when the fourth switch S4 remains off is indicated by the broken line.

The control unit 70 then inputs the first voltage-dividing value Vns1 at a timing (point t33) when the predefined time has elapsed, and calculates Vn1. After calculating Vn1, the control unit 70 turns off the second switch S2 at a timing (point t34) when the predefined time has elapsed. In order to stabilize the voltage-dividing value, the control unit 70 performs the detection range switching process at the timing when the predefined time has elapsed (timing t35). That is, the first voltage-dividing value VnS02 from the first voltage dividing circuit 130 is input, and it is determined whether the first voltage-dividing value VnS02 is greater than or equal to the threshold value Vth and less than the limit value Vmax. Since the first voltage-dividing value Vns02 is greater than or equal to the threshold value Vth and less than the limit value Vmax, the detection range remains at LV3.

The control unit 70 then inputs the first voltage-dividing value Vns2 at the timing when the predefined time has elapsed (at time t36) and calculates Vn2. The control unit 70 calculates the insulation resistance Rz from the calculated Vn1 and Vn2 using the arithmetic expression (13) listed in FIG. 26 to determine whether there is a current leakage.

The effects of the embodiment described above will now be described.

(11) As the insulation resistance Rp increases, the first voltage-dividing value decreases. Therefore, in the second embodiment, the bypass circuit 190, which is a series connection of the resistance R3 and the fourth switch S4, is provided between the positive-side power supply path L1 and the vehicle side ground FG. When the detection range is expanded, that is, when the detection range is set to LV2 or LV3, the fourth switch S4 is turned on, and the potential of the vehicle side ground FG is raised toward the positive side (the positive-side power supply path L1) of the assembled battery 10. In this manner, when the detection range is set to LV2 or LV3, no matter how high the value of the positive-side insulation resistance Rp becomes, the substantial effect of the positive-side insulation resistance Rp can be suppressed by the resistance R3 that is connected in parallel with the insulation resistance Rp.

(12) When the first voltage-dividing values Vnso1 and Vnso2 of the first voltage dividing circuit 130 that have been input are less than the threshold value Vth, the control device 70 turns on the fourth switch S4 to allow current to flow between the positive power supply path L1 and the vehicle side ground FG via the resistor R3. This allows the resistor R3 to be energized at the appropriate timing to suppress the effect of the insulation resistance Rp.

The resistance value of the resistor R3 is less than the positive-side insulation resistance Rp between the positive-side power supply path L1 and the vehicle side ground FG, and is greater than the value allowed as the normal value of the insulation resistance Rp. Therefore, no matter how high the positive-side insulation resistance Rp becomes, its effect can be substantially suppressed by the resistor R3 that is connected in parallel with the insulation resistance Rp.

### Exemplary Modifications of Second Embodiment

The second embodiment described above may be implemented in combination with the first embodiment or an exemplary modification thereof.
In the second embodiment described above, the range change circuit 160 is configured with two stages, and the voltage-dividing ratio can be changed in two steps. In an alternative, the voltage-dividing ratio may be configured as being changeable in one step, or in three or more steps.
In the second embodiment described above, instead of the range change circuit 160, only the resistor Rk1 may be provided. That is, the voltage-dividing ratio of the first voltage dividing circuit 130 may not be changed. In this case, when the first voltage-dividing values Vns01 and Vns02 of the first voltage dividing circuit 130 are less than the threshold value Vth, it is sufficient to turn on the fourth switch S4.
In the above second embodiment, the fourth switch S4 may not be provided. That is, it may be energized at all times via the resistor R3 between the positive-side power supply path L1 and the vehicle side ground FG. In this case, too, the effect of the increase in insulation resistance Rp can be suppressed.
In the above second embodiment, as illustrated in FIG. 12, when the first voltage dividing circuit 130 and the second voltage dividing circuit 40 are provided between the positive-side power supply path L1 and the vehicle side ground FG, a bypass circuit 190 (such as a resistor R3) may be provided between the negative-side power supply path L2 and the vehicle side ground FG.

Although the present disclosure has been described in accordance with the above-described embodiments, it is not limited to such embodiments, but also encompasses various variations and variations within equal scope. In addition, various combinations and forms, as well as other combinations and forms, including only one element, more or less, thereof, are also within the scope and idea of the present disclosure.

What is claimed is:

1. A current leakage detection device for detecting a current leakage between ground and power supply paths connected to terminals of a battery, comprising:
a first voltage dividing circuit connected to a power supply path side at one end and connected to a ground side at another end;
a resistor circuit connected in parallel with the first voltage dividing circuit with one end connected to the power supply path side and another end connected to the ground side;
a switch unit configured to be switchable between energized and de-energized states of the resistor circuit;
a control unit configured to control switching of the switch unit to acquire a first voltage-dividing value from the first voltage dividing circuit and calculate an insulation resistance from the acquired first voltage-dividing value to detect the current leakage, wherein the first voltage dividing circuit includes a range change circuit that changes a voltage-dividing ratio of the first voltage dividing circuit, and
the control unit is configured to, when the first voltage-dividing value of the first voltage dividing circuit is less than a threshold value, change the voltage-dividing ratio of the first voltage dividing circuit to increase the first voltage-dividing value.

2. The current leakage detection device according to claim 1, wherein
the control unit is configured to perform:
a first input step of acquiring the first voltage-dividing value input from the first voltage dividing circuit when the resistor circuit is in the energized state;
a second input step of acquiring the first voltage-dividing value input from the first voltage dividing circuit when the resistor circuit is in the de-energized state; and
a current leakage detection step of detecting the current leakage by calculating the insulation resistance based on the first voltage-dividing value input in the first input step and the first voltage-dividing value input in the second input step, wherein
the control unit is configured to acquire the first voltage-dividing value of the first voltage dividing circuit before the first input step or the second input step, and when the first voltage-dividing value is less than a threshold value, change the voltage-dividing ratio of the first voltage dividing circuit.

3. The current leakage detection device according to claim 1, wherein
the resistor circuit is a second voltage dividing circuit,
the control unit is configured to be capable of acquiring the voltage-dividing values input from the first voltage dividing circuit and the second voltage dividing circuit,
The control unit performs:
a first switching step of controlling the switch unit to place the second voltage dividing circuit in the energized state;
a first input step of acquiring the first voltage-dividing value input from the first voltage dividing circuit and the second voltage-dividing value input from the second voltage dividing circuit when the second voltage dividing circuit is in the energized state after the first switching step;
a second switching step of controlling the switch unit to place the second voltage dividing circuit in the de-energized state after the first input step;
a second input step of acquiring the first voltage-dividing value input from the first voltage dividing circuit when the second voltage dividing circuit is in the de-energized state after the second switching step;
a characterization step of determining whether there is an abnormality in the first voltage dividing circuit and the second voltage dividing circuit based on the first voltage-dividing value and the second voltage-dividing value acquired in the first input step; and
a current leakage detection step of detecting the current leakage by calculating the insulation resistance based on the first voltage-dividing value acquired in the first input step and the first voltage-dividing value acquired in the second input step.

4. The current leakage detection device according to claim 1, wherein
the first voltage dividing circuit comprises a first A detection resistor, a first B detection resistor, a first C detection resistor, and a voltage-dividing ratio changing switch that is connected in series with the first C detection resistor and is switchable between energized and de-energized states of the first C detection resistor,
a series connection of the first C detection resistor and the voltage-dividing ratio changing switch is connected in parallel with the first B detection resistor to form a parallel connection,
the first A detection resistor is connected in series with the parallel connection, and the control unit is configured to change the voltage-dividing ratio of the first voltage dividing circuit by turning on and off the voltage-dividing ratio changing switch.

5. The current leakage detection device according to claim 1, wherein
the first voltage dividing circuit comprises a first A detection resistor, a first B detection resistor, a first C detection resistor, and a voltage-dividing ratio changing switch connected in parallel with the first B detection resistor to switch between energized and de-energized states of the first B detection resistor,
the first A detection resistor, the first B detection resistor and the first C detection resistor are connected in series, and
the control unit is configured to change the voltage-dividing ratio of the first voltage dividing circuit by turning on and off the voltage-dividing ratio changing switch.

6. The current leakage detection device according to claim 1, wherein
the first voltage dividing circuit comprises a first A detection resistor, a first B detection resistor and a first C detection resistor, which are connected in series, and
the control unit is configured to, during normal operation, acquire the first voltage-dividing value from a connection point between the first B detection resistor and the first C detection resistor, and when the acquired first voltage-dividing value is less than a threshold value, change the voltage-dividing ratio of the first voltage dividing circuit by acquiring the first voltage-dividing value from a connection point between the first A detection resistor and the first B detection resistor.

7. The current leakage detection device according to claim 1, wherein
the control unit is configured to detect that there is a leakage current without calculating a value of the insulation resistance, when a voltage across the first voltage dividing circuit, which is calculated based on the first voltage-dividing value and the voltage-dividing ratio input from the first voltage dividing circuit, is less than a determination threshold.

8. The current leakage detection device according to claim 1, wherein
the power supply paths comprise a positive-side power supply path connected to a positive terminal of the battery and a negative-side power supply path connected to a negative terminal of the battery,
the first voltage dividing circuit and the resistor circuit are connected to a first power supply path that is either the positive-side power supply path or the negative-side power supply path,
the current leakage detection device further comprises a resistor provided between the ground and a second power supply path that is either the positive-side power supply path or the negative-side power supply paths and is different from the first power supply path.

9. The current leakage detection device according to claim 8, further comprising:
a switch connected in series with the resistor, wherein
the control unit is configured to, when the first voltage-dividing value acquired from the first voltage dividing circuit is less than a threshold, turn on the switch to pass current between the second power supply path and the ground via the resistor.

10. The current leakage detection device according to claim 9, wherein
a resistance value of the resistor is less than the insulation resistance between the second power supply path and the ground, and is greater than a value that is allowed as a normal value for the insulation resistance.

11. A current leakage detection device for detecting a current leakage between a positive-side power supply path connected to a positive terminal of a battery and ground, and a current leakage between a negative-side power supply path connected to a negative terminal of the battery and ground, comprising:
a first voltage dividing circuit connected to a first power supply path that is either the positive-side power supply path or the negative-side power supply path at one end, and connected to a ground side at another end;
a resistor circuit connected to the first power supply path at one end and connected to the ground side at another end, and connected in parallel with the first voltage dividing circuit;
a switch unit configured to be switchable between energized and de-energized states of the resistor circuit;
a control unit configured to detect a current leakage by controlling switching of the switching unit to acquire first voltage-dividing values from the first voltage dividing circuit and calculate an insulation resistance from the acquired first voltage-dividing values; and
a resistor connected to, at one end, a second power supply path that is different from the first power supply path, among the positive-side power supply path and the negative-side power supply path, and connected to the ground side at another end.

12. The current leakage detection device according to claim 11, further comprising:
a switch connected in series with the resistor, wherein
the control unit is configured to, when the first voltage-dividing values acquired from the first voltage dividing circuit is less than a threshold, turn on the switch to pass current between the second power supply path and the ground via the resistor.

13. The current leakage detection device according to claim 11, wherein
a resistance value of the resistor is less than the insulation resistance between the second power supply path and the ground, and is greater than a value that is allowed as a normal value for the insulation resistance.
